(19) United States
(12) Patent Application Publication
(10) Pub. No.: US 2023/0053037 A1
(43) Pub. Date: Feb. 16, 2023

(54) DISPLAY DEVICE AND METHOD FOR FABRICATION THEREOF

(71) Applicant: Samsung Display Co., LTD., Yongin-si (KR)

(72) Inventors: Jin Woo CHOI, Seoul (KR); Sung Kook PARK, Suwon-si (KR); Sung Eun BAEK, Suwon-si (KR); Byeong Hwa CHOI, Seoul (KR)

(21) Appl. No.: 17/748,832

(22) Filed: May 19, 2022

(30) Foreign Application Priority Data
Aug. 10, 2021 (KR) 10-2021-0105307

(51) Int. Cl. H01L 25/18; H01L 27/15; H01L 23/00

(52) U.S. Cl. CPC H01L 25/18; H01L 27/156; H01L 24/73; H01L 24/29; H01L 24/14; H01L 2224/05573; H01L 2224/05611; H01L 2224/05624; H01L 2224/05644; H01L 2224/05647; H01L 2224/05639; H01L 2224/05686; H01L 2924/0132; H01L 2924/0133; H01L 2224/06051; H01L 2224/13111; H01L 2224/13124; H01L 2224/13147; H01L 2224/13144; H01L 2224/13186; H01L 2924/0549; H01L 2224/13082; H01L 2224/16145; H01L 2224/29017; H01L 2224/30505; H01L 2224/32145; H01L 2224/2761; H01L 2224/73103; H01L 2224/73204; H01L 2224/8113; H01L 2224/83104; H01L 2224/92125; H01L 2224/9211; H01L 24/05; H01L 24/06; H01L 24/13; H01L 24/16; H01L 24/30; H01L 24/32; H01L 24/33; H01L 24/81; H01L 24/83; H01L 24/92; H01L 24/08; H01L 2224/08225; H01L 2224/29144; H01L 2224/29147; H01L 2224/29124; H01L 2224/29111; H01L 2224/29186; H01L 2224/29082; H01L 2224/29023; H01L 2924/0544; H01L 2924/0504; H01L 2924/059; H01L 2224/33517; H01L 2224/1403

(57) ABSTRACT

A display device and method for fabrication thereof includes a plurality of pixel electrodes and common electrode connection parts that are spaced from each other on a first substrate, a plurality of light emitting elements on the plurality of pixel electrodes, a plurality of common electrode elements on the common electrode connection parts, and a common electrode layer on the plurality of light emitting elements and the plurality of common electrode elements, wherein each of the plurality of light emitting element includes a first semiconductor layer, a second semiconductor layer, and an active layer between the first semiconductor layer and the second semiconductor layer, each of the plurality of common electrode elements includes at least the second semiconductor layer, and the common electrode layer includes a same material as the second semiconductor layer to be connected to the second semiconductor layers of the plurality of light emitting elements.

### CROSS-REFERENCE TO RELATED APPLICATION

This application claims priority to and the benefit of Korean Patent Application No. 10-2021-0105307 filed on Aug. 10, 2021 in the Korean Intellectual Property Office, the entire content of which is incorporated by reference herein.

### BACKGROUND

### 1. Field

The present disclosure relates to a display device and a method for fabrication thereof.

### 2. Description of the Related Art

As the information society develops, demands for display devices for displaying images are increasing in various forms. The display devices may be flat panel displays such as liquid crystal displays, field emission displays, and light emitting displays. The light emitting displays may include an organic light emitting display including an organic light emitting diode element as a light emitting element and an inorganic light emitting display including an inorganic semiconductor element as a light emitting element.

Recently, a head-mounted display including a light emitting display has been developed. The head-mounted display is a virtual reality (VR) or augmented reality (AR) glasses-type monitor device that is worn by a user in the form of glasses or a helmet and forms a focus at a short distance in front of the eyes.

### SUMMARY

Aspects and features of embodiments of the present disclosure provide an ultrahigh-resolution display device including inorganic light emitting elements and a large number of emission areas per unit area.

Aspects and features of embodiments of the present disclosure also provide a display device including light emitting elements disposed in a display area and further including elements disposed in an area other than the display area to allow the light emitting elements in the display area to have a uniform quality, and a method for fabrication thereof.

However, aspects and features of embodiments of the present disclosure are not limited to those set forth herein. The above and other aspects and features of embodiments of the present disclosure will become more apparent to one of ordinary skill in the art to which the present disclosure pertains by referencing the detailed description of the present disclosure given below.

A method for fabrication of a display device according to one or more embodiments includes forming uniform semiconductor elements regardless of positions on a common electrode layer and then dividing the semiconductor elements into different elements according to areas. Accordingly, the display device may include light emitting elements disposed in a display area and non-light emitting elements disposed in a non-display area, and the light emitting elements in the display area may be formed to have a uniform quality and density. Because the display device according to one or more embodiments is fabricated by the method for fabrication of a display device described above, the light emitting elements in the display area may be formed to have a uniform quality and density, such that a display quality may be improved.

The effects, aspects, and features of embodiments of the present disclosure are not limited to the aforementioned effects, aspects, and features and various other effects, aspects, and features are included in the specification.

According to one or more embodiments of the disclosure, a display device includes: a plurality of pixel electrodes and common electrode connection parts spaced from each other on a first substrate, a plurality of light emitting elements on the plurality of pixel electrodes, a plurality of common electrode elements on the common electrode connection parts, and a common electrode layer on the plurality of light emitting elements and the plurality of common electrode elements, wherein each of the plurality of the light emitting element includes a first semiconductor layer, a second semiconductor layer, and an active layer between the first semiconductor layer and the second semiconductor layer, each of the plurality of common electrode elements includes at least the second semiconductor layer, and the common electrode layer includes a same material as the second semiconductor layer to be connected to the second semiconductor layers of the plurality of light emitting elements and the second semiconductor layers of the plurality of common electrode elements.

Each of the plurality of common electrode elements may include the active layer on one surface of the second semiconductor layer, and the first semiconductor layer on the active layer, the plurality of light emitting elements may include first light emitting elements including a first active layer configured to emit light of a first color and second light emitting elements including a second active layer different from the first active layer and configured to emit light of a second color, and the plurality of common electrode elements may include first common electrode elements including the first active layer and second common electrode elements including the second active layer.

The display device may further include first connection electrodes on one surfaces of the first semiconductor layers of the plurality of light emitting elements, second connection electrodes between the first connection electrodes and the pixel electrodes, and third connection electrodes on the plurality of common electrode elements, wherein the second connection electrodes may be in direct contact with the plurality of pixel electrodes, respectively, and the third connection electrodes are in direct contact with the common electrode connection parts, respectively.

A third connection electrode of the third connection electrodes may be on side surfaces of a common electrode element of the plurality of common electrode elements to be in direct contact with each of the first semiconductor layer and the second semiconductor layer.

The plurality of light emitting elements may further include third light emitting elements including a third active layer different from the first active layer and the second active layer and configured to emit light of a third color, and the plurality of common electrode elements may further include third common electrode elements including the third active layer.

The display device may further include connection electrodes directly on the second semiconductor layers of the plurality of common electrode elements and in direct contact with the common electrode connection parts.

The display device may further include an insulating layer around side surfaces of the plurality of light emitting elements and having portions directly on the common electrode layer, reflective layers around the side surfaces of the plurality of light emitting elements on the insulating layer, and a base layer on the common electrode layer and including an undoped semiconductor.

The display device may further include a plurality of dummy elements each including the first semiconductor layer, the active layer, and the second semiconductor layer and located on the first substrate, wherein the plurality of dummy elements may have outer surfaces covered by the insulating layer.

The second semiconductor layer of one of the plurality of dummy elements may be connected to the common electrode layer, the one of the plurality of dummy element not being electrically connected to any of the plurality of pixel electrodes.

The plurality of light emitting elements may include first light emitting elements including a first active layer to emit light of a first color and second light emitting elements including a second active layer different from the first active layer and configured to emit light of a second color, and the plurality of dummy elements may include first dummy elements including the first active layer and second dummy elements including the second active layer.

Each of the plurality of dummy elements may be spaced from the first substrate.

According to one or more embodiments of the present disclosure, a display device includes: a first substrate including a display area and a non-display area around the display area, a plurality of pixel electrodes spaced from each other on the first substrate in the display area, a plurality of common electrode connection parts on the first substrate in a common electrode area in the non-display area that is at one side of the display area, a plurality of light emitting elements on corresponding ones of the plurality of pixel electrodes, a plurality of common electrode elements on corresponding ones of the plurality of common electrode connection parts, a common electrode layer on the plurality of light emitting elements and the plurality of common electrode elements in the display area and the non-display area, and a plurality of connection electrodes between the plurality of light emitting elements and the plurality of pixel electrodes and between the plurality of common electrode elements and the plurality of common electrode connection parts, wherein at least some of the plurality of connection electrodes are on side surfaces of the plurality of common electrode elements.

Each of the plurality of light emitting elements and the plurality of common electrode elements may include a first semiconductor layer including a p-type semiconductor, a second semiconductor layer on the first semiconductor layer and including an n-type semiconductor, and an active layer between the first semiconductor layer and the second semiconductor layer, wherein one of the plurality of connection electrodes on a corresponding one of the plurality of common electrode elements may be in contact with the first semiconductor layer and the second semiconductor layer of the one of the plurality of common electrode elements.

The plurality of light emitting elements may include first light emitting elements including a first active layer configured to emit light of a first color and second light emitting elements including a second active layer different from the first active layer and configured to emit light of a second color, wherein the plurality of common electrode elements may include first common electrode elements including the first active layer and second common electrode elements including the second active layer.

The display device may further include a plurality of dummy elements in an area other than the common electrode area in the non-display area, each of the plurality of dummy elements including the first semiconductor layer, the active layer, and the second semiconductor layer, the of the plurality of dummy elements dummy elements may include first dummy elements including the first active layer and second dummy elements including the second active layer.

The common electrode layer may include an n-type semiconductor integrated with the second semiconductor layers of the plurality of light emitting elements, the plurality of common electrode elements, and the plurality of dummy elements.

According to one or more embodiments of the present disclosure, a method for fabrication of a display device, including: forming a support layer on a common electrode layer including an n-type semiconductor, forming a plurality of holes penetrating through the support layer, and forming a plurality of semiconductor elements in the holes, each of the plurality of semiconductor elements including a first semiconductor layer that is a p-type semiconductor, a second semiconductor layer that is an n-type semiconductor, and an active layer between the first semiconductor layer and the second semiconductor layer, forming a plurality of light emitting elements by forming an insulating layer covering the plurality of semiconductor elements and the common electrode layer and removing portions of the insulating layer to expose upper surfaces of the first semiconductor layers of some of the plurality of semiconductor elements, forming first connection electrodes on the exposed first semiconductor layers of the plurality of light emitting elements and forming reflective layers on the insulating layer to be around side surfaces of the plurality of light emitting elements and the plurality of semiconductor elements, forming a plurality of common electrode elements by removing portions of the insulating layer and the reflective layers to expose outer surfaces of some other of the plurality of semiconductor elements, forming second connection electrodes on the first connection electrodes and third connection electrodes on at least side surfaces of the plurality of common electrode elements, and disposing the plurality of light emitting elements and the plurality of common electrode elements on a circuit substrate including a plurality of pixel electrodes and common electrode connection parts.

In the forming of the plurality of common electrode elements, the insulating layer and the reflective layers on some other of the plurality of semiconductor elements may be not removed, such that a plurality of dummy elements are formed, and the third connection electrodes may be on at least the side surfaces of the plurality of common electrode elements to be in direct contact with each of the first semiconductor layers and the second semiconductor layers.

The plurality of semiconductor elements may include first semiconductor elements including a first active layer and second semiconductor elements including a second active layer, and the forming of the plurality of semiconductor elements may include forming first holes penetrating through the support layer and forming the second semiconductor elements on the common electrode layer exposed by the first holes, and forming second holes penetrating through the support layer and forming the first semiconductor elements on the common electrode layer exposed by the second holes.

The plurality of light emitting elements may include first light emitting elements including the first active layer and second light emitting elements including the second active layer, and the plurality of common electrode elements may include first common electrode elements including the first active layer and second common electrode elements including the second active layer.

### BRIEF DESCRIPTION OF THE DRAWINGS

The above and other aspects and features of the present disclosure will become more apparent by describing in detail embodiments thereof with reference to the attached drawings, in which:

FIG. 1 is a plan view of a display device according to one or more embodiments;

FIG. 2 is a schematic plan view of a circuit substrate of the display device of FIG. 1 according to one or more embodiments;

FIG. 3 is a schematic plan view of a display substrate of the display device of FIG. 1 according to one or more embodiments;

FIG. 4 is a plan view of the circuit substrate and the display substrate of FIGS. 2 and 3;

FIG. 5 is an enlarged view of a portion A of FIG. 4;

FIG. 6 is an enlarged view of a portion B of FIG. 5;

FIG. 7 is a cross-sectional view taken along the line I-I′ of FIG. 5;

FIG. 8 is a cross-sectional view taken along the line II-II′ of FIG. 5;

FIG. 9 is a cross-sectional view taken along the line III-III′ of FIG. 5;

FIG. 10 is a cross-sectional view taken along the line IV-IV′ of FIG. 5;

FIG. 11 is a flowchart illustrating a method for fabrication of the display device of FIG. 1 according to one or more embodiments;

FIGS. 12 to 28 are cross-sectional views sequentially illustrating processes of fabrication of the display device according to one or more embodiments;

FIG. 29 is a cross-sectional view illustrating a portion of a display device according to one or more embodiments;

FIGS. 30 and 31 are cross-sectional views illustrating some of processes for fabrication of the display device of FIG. 29;

FIG. 32 is a cross-sectional view illustrating a portion of a display device according to one or more embodiments;

FIGS. 33 and 34 are cross-sectional views illustrating portions of display devices according to one or more embodiments;

FIG. 35 is a plan view illustrating a relative layout of light emitting elements disposed in a display area of a display device according to one or more embodiments;

FIG. 36 is a plan view illustrating a relative layout of light emitting elements and dummy elements disposed on a display substrate in the display device of FIG. 35;

FIG. 37 is a plan view illustrating a relative layout of light emitting elements disposed in a display area of the display device according to one or more embodiments;

FIG. 38 is a plan view illustrating a relative layout of light emitting elements disposed in a display area of a display device according to one or more embodiments;

FIG. 39 is a cross-sectional view illustrating a portion of the display device of FIG. 38;

FIG. 40 is a plan view illustrating a relative layout of light emitting elements disposed in a display area of a display device according to one or more embodiments;

FIG. 41 is a plan view illustrating a portion of a display substrate and a circuit substrate of a display device according to one or more embodiments;

FIG. 42 is a cross-sectional view taken along the line V-V′ of FIG. 41;

FIG. 43 is a cross-sectional view illustrating one of processes for fabrication of the display device of FIG. 41;

FIG. 44 is an equivalent circuit diagram of one pixel of a display device according to one or more embodiments;

FIGS. 45 to 47 are schematic views illustrating a device including a display device according to one or more embodiments; and

FIGS. 48 and 49 are views illustrating a transparent display device including a display device according to one or more embodiments.

### DETAILED DESCRIPTION

The present disclosure will now be described more fully hereinafter with reference to the accompanying drawings, in which embodiments of the present disclosure are shown. This disclosure may, however, be embodied in different forms and should not be construed as limited to the embodiments set forth herein. Rather, these embodiments are provided so that this disclosure will be thorough and complete, and will fully convey the scope of the present disclosure to those skilled in the art.

It will also be understood that when a layer is referred to as being “on” another layer or substrate, it can be directly on the other layer or substrate, or intervening layers may also be present. The same reference numbers indicate the same components throughout the specification.

It will be understood that, although the terms “first,” “second,” etc. may be used herein to describe various elements, these elements should not be limited by these terms. These terms are only used to distinguish one element from another element. For instance, a first element discussed below could be termed a second element without departing from the teachings of the present disclosure. Similarly, the second element could also be termed the first element.

Hereinafter, embodiments will be described with reference to the accompanying drawings.

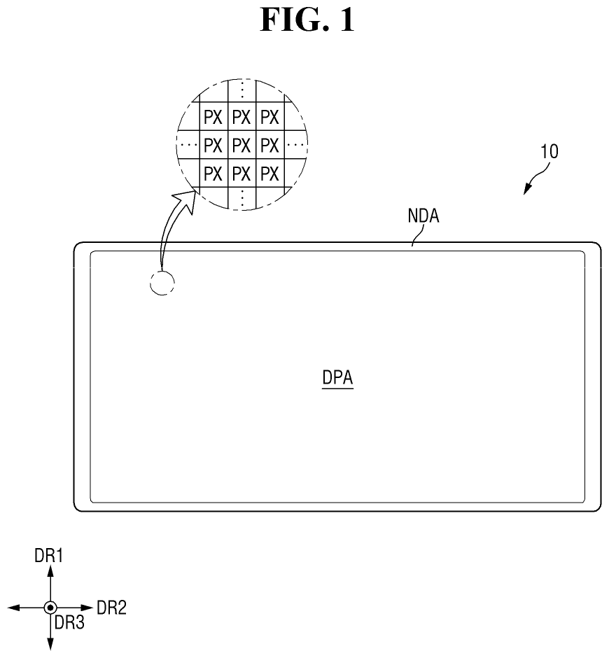

FIG. 1 is a plan view of a display device according to one or more embodiments.

Referring to FIG. 1, a display device 10 displays a moving image or a still image. The display device 10 may refer to all electronic devices that provide display screens. For example, televisions, laptop computers, monitors, billboards, the Internet of Things (IoT), mobile phones, smartphones, tablet personal computers (PCs), electronic watches, smart watches, watch phones, head mounted displays, mobile communication terminals, electronic notebooks, electronic books, portable multimedia players (PMPs), navigation devices, game machines, digital cameras, camcorders, and the like, which provide display screens, may be included in the display device 10.

The display device 10 includes a display panel providing a display screen. Examples of the display panel include an inorganic light emitting diode display panel, an organic light emitting display panel, a quantum dot light emitting display panel, a plasma display panel, a field emission display panel, and the like. Hereinafter, a display device in which inorganic light emitting diodes are disposed on a semiconductor circuit substrate will be described as an example of the display panel, but the present disclosure is not limited thereto, and the same technical idea may also be applied to other display panels if applicable.

A shape of the display device 10 may be variously changed. For example, the display device 10 may have a shape such as a rectangular shape with a width greater than a length, a rectangular shape with a length greater than a width, a square shape, a rectangular shape with rounded corners (or vertices), other polygonal shapes, or a circular shape. A shape of a display area DPA of the display device 10 may also be similar to an overall shape of the display device 10. In FIG. 1, the display device 10 having a rectangular shape with a greater length in a second direction DR2 is illustrated.

In the specification, a first direction DR1 refers to a length direction of the display device 10, the second direction DR2 refers to a width direction of the display device 10, and a third direction DR3 refers to a thickness direction of the display device 10. The terms “above”, “top”, and “upper surface” as used herein refer to one side in the third direction DR3. The terms “under”, “bottom”, and “lower surface” as used herein refer to the other side in the third direction DR3. “Left”, “right”, “upper”, and “lower” refer to directions when the drawings are viewed in a plan view. For example, “upper” and “lower” refer to the first direction DR1, and “left” and “right” refer to the second direction DR2.

The display device 10 may include a display area DPA and a non-display area NDA. The display area DPA is an area in which an image may be displayed, and the non-display area NDA is an area in which an image is not displayed. The display area DPA may also be referred to as an active area, and the non-display area NDA may also be referred to as a non-active area. The display area DPA may be generally disposed at the center of the display device 10.

The non-display area NDA may be disposed around the display area DPA along the edge or periphery of the display area DPA. The non-display area NDA may entirely or partially surround the display area DPA. The display area DPA may have a rectangular shape, and the non-display area NDA may be disposed adjacent to four sides of the display area DPA. The non-display areas NDA may constitute a bezel of the display device 10. Lines or circuit drivers included in the display device 10 may be disposed or external devices may be mounted, in each of the non-display areas NDA.

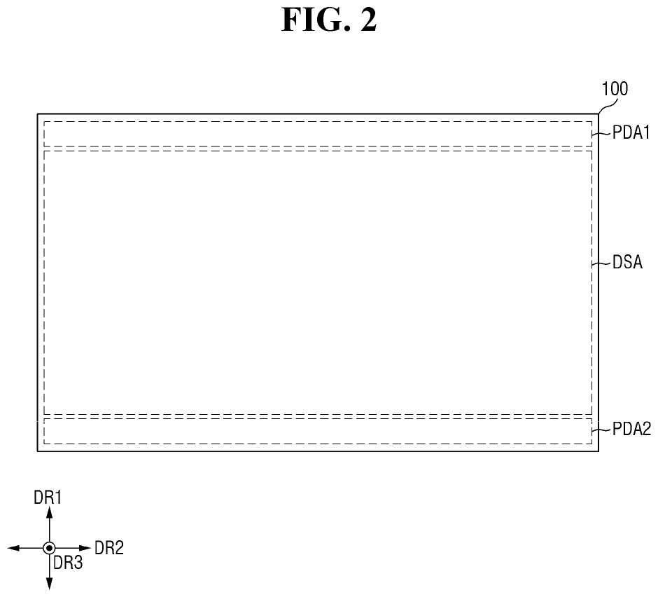

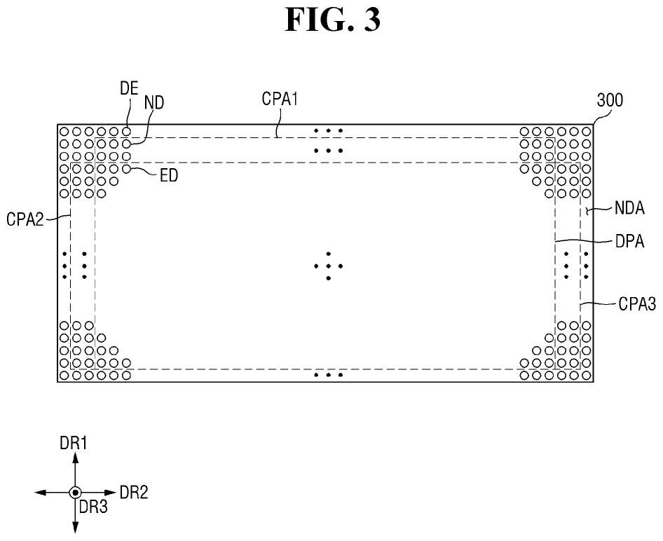

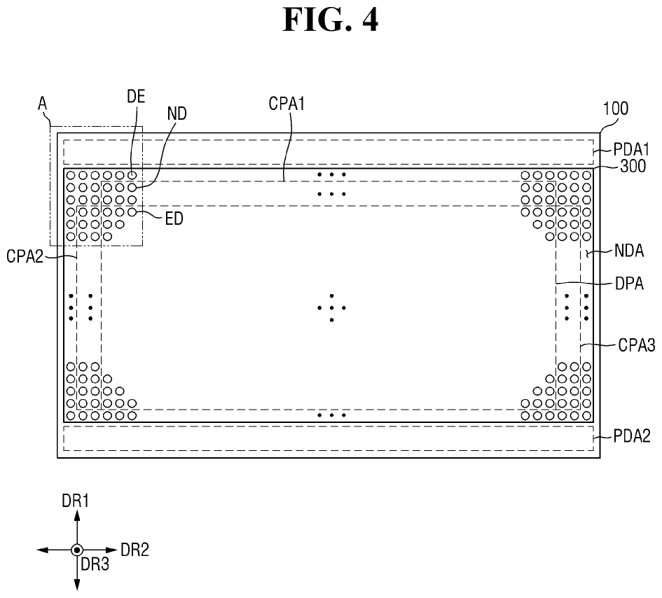

FIG. 2 is a schematic plan view of a circuit substrate of the display device of FIG. 1 according to one or more embodiments. FIG. 3 is a schematic plan view of a display substrate of the display device of FIG. 1 according to one or more embodiments. FIG. 4 is a plan view of the circuit substrate and the display substrate of FIGS. 2 and 3.

Referring to FIGS. 2 to 4 in conjunction with FIG. 1, the display device 10 according to one or more embodiments may include a circuit substrate 100 and a display substrate 300.

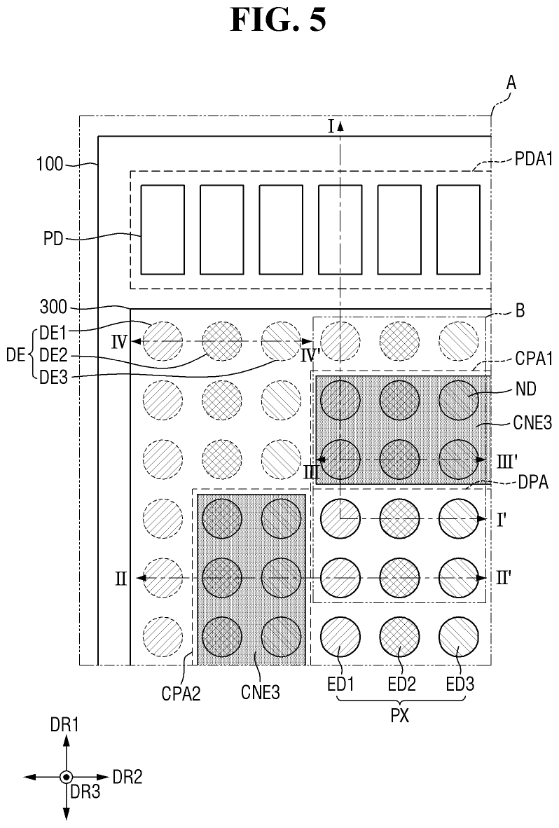

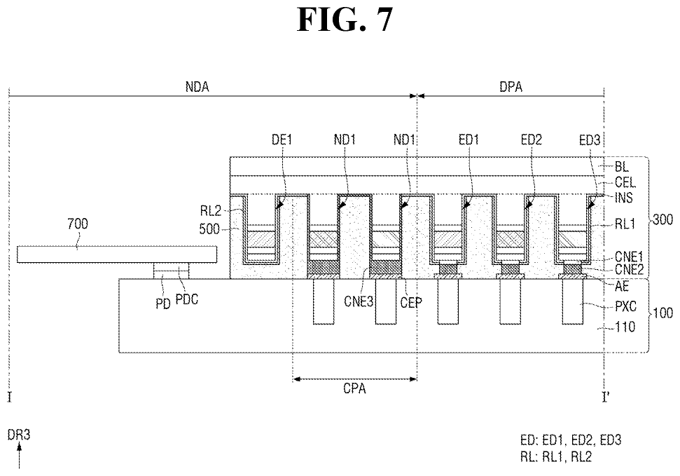

The circuit substrate 100 may include pixel circuit parts PXC (see FIG. 7) electrically connected to light emitting elements ED included in the display substrate 300 and a plurality of pads PD (see FIG. 5) electrically connected to lines of the pixel circuit parts PXC. The circuit substrate 100 may include a display substrate area DSA positioned at a central portion, a non-display area NDA disposed around the display substrate area DSA, and pad areas PDA1 and PDA2 disposed on both sides of the display substrate area DSA in the first direction DR1 in the non-display area NDA. The display substrate area DSA of the circuit substrate 100 is an area on which the display substrate 300 is disposed, and the pixel circuit parts PXC may be disposed in the display substrate area DSA. The pad areas PDA1 and PDA2 may include a first pad area PDA1 disposed on the upper side of the display substrate area DSA, which is one side of the display substrate area DSA in the first direction DR1, and a second pad area PDA2 disposed on the lower side of the display substrate area DSA, which is the other side of the display substrate area DSA in the first direction DR1. A plurality of pads PD electrically connected to the pixel circuit parts PXC may be disposed in each of the pad areas PDA1 and PDA2 of the circuit substrate 100.

The plurality of pads PD may be disposed to be spaced from each other in the second direction DR2. The plurality of pads PD may be disposed on an upper surface of the circuit substrate 100 and may be electrically connected to circuit board pads PDC (see FIG. 7) of a circuit board 700 (see FIG. 7).

The display substrate 300 may be disposed on the circuit substrate 100. The display substrate 300 may include a display area DPA and a non-display area NDA, and may include common electrode areas CPA1, CPA2, and CPA3 adjacent to the display area DPA as portions of the non-display area NDA. The common electrode areas CPA1, CPA2, and CPA3 may include a first common electrode area CPA1 disposed on the upper side of the display area DPA, a second common electrode area CPA2 disposed on the left side of the display area DPA, which is one side of the display area DPA in the second direction DR2, and a third common electrode area CPA3 disposed on the right side of the display area DPA, which is the other side of the display area DPA in the second direction DR2.

The display substrate 300 may include a plurality of light emitting elements ED disposed in the display area DPA. The light emitting elements ED may be arranged to be spaced from each other in the first direction DR1 and the second direction DR2 in the display area DPA, and may be disposed to correspond to a plurality of pixel electrodes AE (see FIG. 7) connected to the pixel circuit parts PXC of the circuit substrate 100. The light emitting elements ED may emit light by receiving electrical signals applied from the pixel circuit parts PXC of the circuit substrate 100.

In the display device 10 according to one or more embodiments, the display substrate 300 may further include a plurality of common electrode elements ND and dummy elements DE having the same structure as the light emitting elements ED and disposed in areas other than the display area DPA. The common electrode elements ND and the dummy elements DE may include common electrode elements ND disposed in the common electrode areas CPA1, CPA2, and CPA3 of the non-display area NDA and dummy elements DE disposed in the non-display area NDA other than the common electrode areas CPA1, CPA2, and CPA3. Each of the common electrode elements ND and the dummy elements DE may have the same structure as the light emitting element ED and include the same material as the light emitting element ED. However, each of the common electrode elements ND and the dummy elements DE may not be electrically connected to each of the pixel circuit parts PXC of the circuit substrate 100 or may be a non-light emitting element that does not emit light because both ends of the element itself are short-circuited. In the display device 10, only some of elements formed on a front surface of the display substrate 300 may be the light emitting elements ED electrically connected to the circuit substrate 100 to emit light, and the other elements may remain as the common electrode elements ND and the dummy elements DE, which are the non-light emitting elements. In the display device 10, the light emitting elements ED disposed in the display area DPA may have a uniform quality regardless of their positions by disposing the common electrode elements ND and the dummy elements DE having the same structure as the light emitting elements ED in the areas other than the display area DPA of the display substrate 300. Differences in quality and density between the light emitting elements ED adjacent to the common electrode areas CPA1, CPA2, and CPA3 outside the display area DPA and the light emitting elements ED disposed at the center of the display area DPA may be decreased, such that a quality of the display device 10 may be improved. Hereinafter, a structure of the display device 10 will be described in more detail with reference to other drawings.

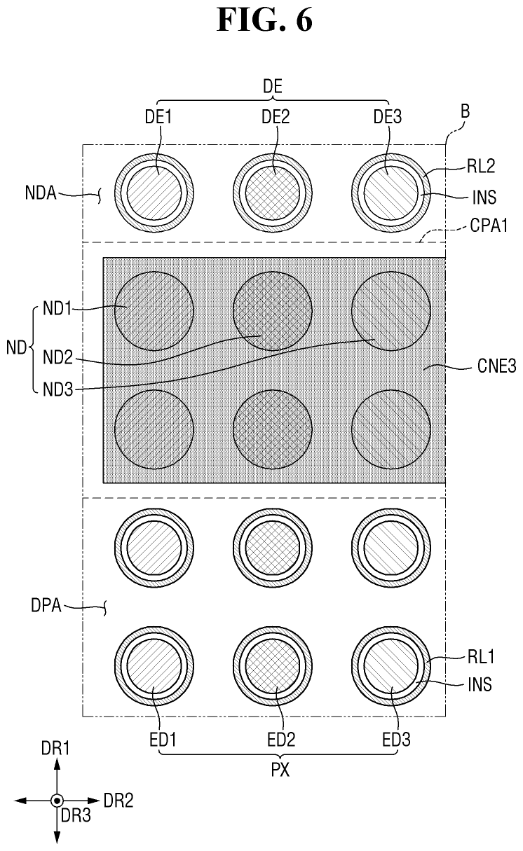

FIG. 5 is an enlarged view of a portion A of FIG. 4. FIG. 6 is an enlarged view of a portion B of FIG. 5. FIG. 5 illustrates a portion of the circuit substrate 100 and the display substrate 300 at a corner portion of the display device 10 in an enlarged form, and FIG. 6 schematically illustrates a layout of elements disposed in the display substrate 300.

Referring to FIGS. 5 and 6, the display substrate 300 of the display device 10 may include a plurality of pixels PXs disposed in the display area DPA. The plurality of pixels PX may include a plurality of light emitting elements ED, and may be arranged along a matrix direction, similar to the light emitting elements ED. For example, the plurality of pixels PX and the plurality of light emitting elements ED may be arranged along rows and columns of a matrix. Each of the pixels PX may include one or more light emitting elements ED to display a specific color. In the display device 10, one pixel PX including a plurality of light emitting elements ED: ED1, ED2, and ED3 may have a minimum light emitting unit.

For example, one pixel PX may include a first light emitting element ED1, a second light emitting element ED2, and a third light emitting element ED3. The first light emitting element ED1 may emit light of a first color, the second light emitting element ED2 may emit light of a second color, and the third light emitting element ED3 may emit light of a third color. As an example, the first color may be red, the second color may be green, and the third color may be blue. However, the present disclosure is not limited thereto, and the respective light emitting elements ED may emit light of the same color. In one or more embodiments, one pixel PX may include three light emitting elements ED1, ED2, and ED3, but is not limited thereto. For example, one pixel PX may include four or more light emitting elements. Each of the light emitting elements ED may have a circular shape in a plan view. However, the present disclosure is not limited thereto. For example, the light emitting element ED may have a polygonal shape such as a quadrangular shape, an elliptical shape, or irregular shape other than the circular shape.

The plurality of light emitting elements ED1, ED2, and ED3 may be disposed to be spaced from each other in the first direction DR1 and the second direction DR2. A plurality of first light emitting elements ED1, second light emitting elements ED2, and third light emitting elements ED3 may be repeatedly disposed to be spaced from each other in the first direction DR1, respectively, and the first light emitting elements ED1, the second light emitting elements ED2, and the third light emitting elements ED3 may be alternately arranged along the second direction DR2. The first light emitting elements ED1, the second light emitting elements ED2, and the third light emitting elements ED3 may be sequentially disposed along the second direction DR2, and such an arrangement may be repeated. Each of the light emitting elements ED may be electrically connected to a pixel electrode AE (see FIG. 7) of the circuit substrate 100 through a first connection electrode CNE1 (see FIG. 7) and a second connection electrode CNE2 (see FIG. 7) to be described later. In addition, each of the light emitting elements ED may be electrically connected to a common electrode layer CEL (see FIG. 7) of the display substrate 300.

A plurality of common electrode elements ND and third connection electrodes CNE3 may be disposed in the common electrode areas CPA1, CPA2, and CPA3 of the non-display area NDA. The plurality of common electrode elements ND may be spaced from each other in the first direction DR1 and the second direction DR2 in the common electrode areas CPA1, CPA2, and CPA3. According to one or more embodiments, the common electrode element ND may include a first common electrode element ND1, a second common electrode element ND2, and a third common electrode element ND3 disposed to be spaced from each other. An arrangement of the plurality of common electrode elements ND may be substantially the same as that of the light emitting elements ED.

For example, an interval and a direction where the common electrode elements ND are spaced from other adjacent common electrode elements ND may be substantially the same as an interval and a direction where the plurality of light emitting elements ED are spaced from each other. A plurality of first common electrode elements ND1, second common electrode elements ND2, and third common electrode elements ND3 may be repeatedly disposed to be spaced from each other along the first direction DR1, respectively, and the first common electrode elements ND1, the second common electrode elements ND2, and the third common electrode element ND3 may be alternately arranged along the second direction DR2. The first common electrode elements ND1, the second common electrode elements ND2, and the third common electrode element ND3 are sequentially disposed along the second direction DR2, and such an arrangement may be repeated.

The first common electrode elements ND1 may be spaced from the first light emitting elements ED1 in the first direction DR1 and may be disposed in the same column as the first light emitting elements ED1, the second common electrode elements ND2 may be spaced from the second light emitting elements ED2 in the first direction DR1 and may be disposed in the same column as the second light emitting elements ED2, and the third common electrode elements ND3 may be spaced from the third light emitting elements ED3 in the first direction DR1 and may be disposed in the same column as the third light emitting elements ED3.

It has been illustrated in FIG. 5 that common electrode elements ND disposed in two rows are arranged in the first common electrode area CPA1 and common electrode elements ND disposed in two rows are arranged in the second common electrode area CPA2, but the present disclosure is not limited thereto. In one or more embodiments, common electrode elements ND disposed in a larger number or a smaller number of rows and columns may be disposed in one common electrode area CPA1, CPA2, or CPA3.

The third connection electrodes CNE3 may be disposed in each of the common electrode areas CPA1, CPA2, and CPA3 to overlap the plurality of common electrode elements ND. One third connection electrode CNE3 may cover the plurality of common electrode elements ND, but is not limited thereto. In some embodiments, the third connection electrodes CNE3 may also be formed to correspond to each of the common electrode elements ND. The third connection electrodes CNE3 may be electrically connected to each of common electrode connection parts CEP (see FIG. 7) of the circuit substrate 100 to be described later and the common electrode layer CEL of the display substrate 300.

A plurality of dummy elements DE may be disposed in the non-display area NDA other than the common electrode areas CPA1, CPA2, and CPA3. The plurality of dummy elements DE may not be electrically connected to the pixel circuit parts PXC of the circuit substrate 100, unlike the light emitting elements ED. The dummy elements DE may be non-light emitting elements disposed in the non-display area NDA.

The dummy elements DE may be spaced from each other in the first direction DR1 and the second direction DR2 in the non-display area NDA of the display substrate 300. According to one or more embodiments, the dummy element DE may include a first dummy element DE1, a second dummy element DE2, and a third dummy element DE3 disposed to be spaced from each other along the second direction. An arrangement of the plurality of dummy elements DE may be substantially the same as that of the light emitting elements ED and the common electrode elements ND. For example, an interval and a direction where the dummy elements DE are spaced from other adjacent dummy elements DE may be substantially the same as an interval and a direction where the plurality of light emitting elements ED are spaced from each other. A plurality of first dummy elements DE1, second dummy elements DE2, and third dummy elements DE3 may be repeatedly disposed to be spaced from each other along the first direction DR1, respectively, and the first dummy elements DE1, the second dummy elements DE2, and the third dummy elements DE3 may be alternately arranged along the second direction DR2. The first dummy elements DE1, the second dummy elements DE2, and the third dummy elements DE3 may be sequentially disposed along the second direction DR2, and such an arrangement may be repeated. The first dummy elements DE1 may be spaced from the first light emitting elements ED1 in the first direction DR1 and may be disposed in the same column as the first light emitting elements ED1, the second dummy elements DE2 may be spaced from the second light emitting elements ED2 in the first direction DR1 and may be disposed in the same column as the second light emitting elements ED2, and the third dummy elements DE3 may be spaced from the third light emitting elements ED3 in the first direction DR1 and may be disposed in the same column as the third light emitting elements ED3.

Outer surfaces of the light emitting elements ED and the dummy elements DE may be surrounded by an insulating layer INS. The outer surfaces of the light emitting elements ED and the dummy elements DE may be surrounded by reflective layers RL1 and RL2, respectively. The insulating layer INS may be disposed on a side surface of each of the light emitting elements ED and the dummy elements DE, and may also be disposed on one surface of a common electrode layer CEL (see FIG. 7) to be described later. The insulating layer INS may partially surround the light emitting elements ED and the dummy elements DE, and portions of the insulating layer INS surrounding the light emitting elements ED and the dummy elements DE may be spaced from each other in the first direction DR1 and the second direction DR2 in a plan view. The insulating layer INS may protect each of the plurality of light emitting elements ED and dummy elements DE, and may insulate the plurality of light emitting elements ED and dummy elements DE from other layers. The insulating layer INS may include an inorganic insulating material such as silicon oxide (SiOₓ), silicon nitride (SiNₓ), silicon oxynitride (SiOₓN_{y}), aluminum oxide (AlOₓ), or aluminum nitride (AlNₓ).

First reflective layers RL1 may be disposed to be around (or surround) side surfaces of the light emitting elements ED. The first reflective layers RL1 may be disposed to correspond to the respective light emitting elements ED in the display area DPA, and may be disposed directly on the insulating layer INS disposed on the side surfaces of the light emitting elements ED. Because the first reflective layers RL1 are disposed to correspond to and surround the light emitting elements ED spaced apart from each other, the first reflective layers RL1 that are different from each other may be spaced from each other in the first direction DR1 and the second direction DR2 in a plan view. The first reflective layers RL1 may reflect light emitted from the light emitting elements ED.

Second reflective layers RL2 may be disposed to be around (or surround) side surfaces of the dummy elements DE. The second reflective layers RL2 may be disposed to correspond to the respective dummy elements DE in the non-display area NDA, and may be disposed directly on the insulating layer INS disposed on the side surfaces of the dummy elements DE. Because the second reflective layers RL2 are disposed to correspond to and surround the dummy elements DE spaced from each other, the second reflective layers RL2 that are different from each other may be spaced from each other in the first direction DR1 and the second direction DR2 in a plan view.

The first reflective layer RL1 and the second reflective layer RL2 may include a metal material having high reflectivity, such as aluminum (Al). A thickness of each of the first reflective layer RL1 and the second reflective layer RL2 may be approximately 0.1 μm, but is not limited thereto.

A plurality of pads PD may be disposed in the pad area PDA of the circuit substrate 100. The respective pads PD may be electrically connected to circuit board pads PDC disposed on an external circuit board 700. The plurality of pads PD may be arranged to be spaced from each other in the second direction DR2 in the pad area PDA. A layout of the respective pads PD may be designed according to the number of light emitting elements ED disposed in the display area DPA and a layout of lines electrically connected to the light emitting elements ED. A layout of the pads PD may be variously modified according to a layout of the light emitting elements ED and the layout of the lines electrically connected to the light emitting elements ED.

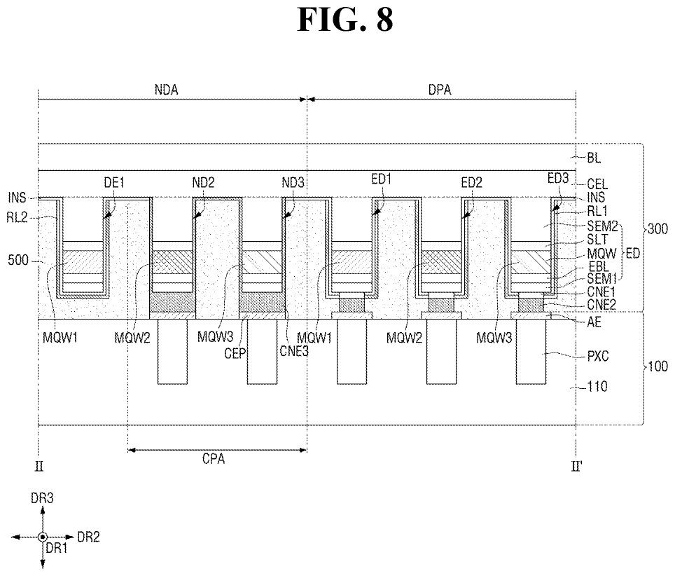

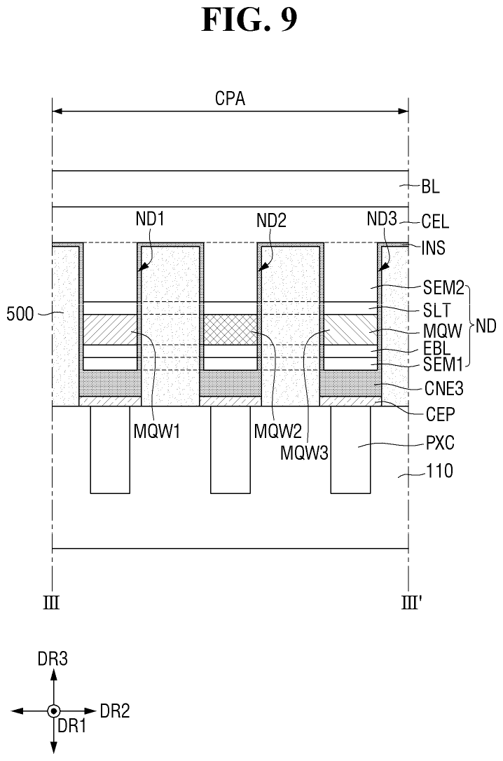

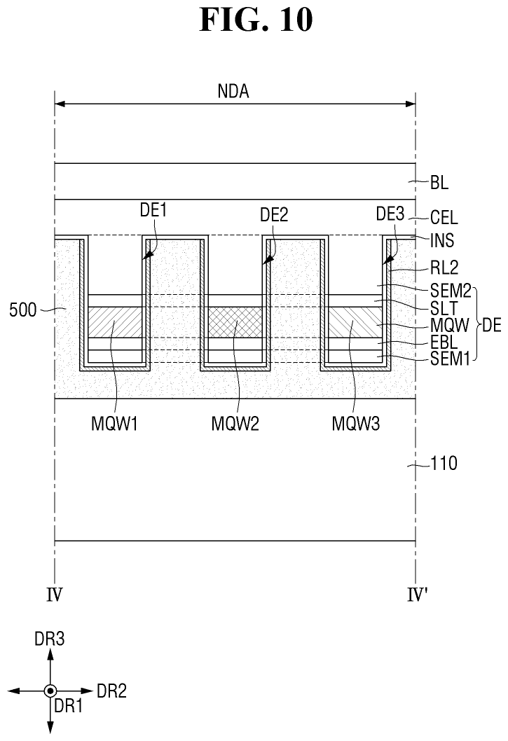

FIG. 7 is a cross-sectional view taken along the line I-I′ of FIG. 5. FIG. 8 is a cross-sectional view taken along the line II-II′ of FIG. 5. FIG. 9 is a cross-sectional view taken along the line III-III′ of FIG. 5. FIG. 10 is a cross-sectional view taken along the line IV-IV′ of FIG. 5. FIGS. 7 and 8 illustrate cross-sections crossing the plurality of light emitting elements ED, common electrode elements ND, and dummy elements DE disposed in the non-display area NDA and the display area DPA of the display substrate 300.

Referring to FIGS. 7 to 10 in conjunction with FIGS. 5 and 6, in the display device 10 according to one or more embodiments, the circuit substrate 100 may include a first substrate 110, pixel circuit parts PXC, and a plurality of pads PD, and the display substrate 300 may include light emitting elements ED, common electrode elements ND, and dummy elements DE, in addition to other elements (e.g., see FIG. 5-10). The display device 10 may further include a filling layer 500 disposed between the circuit substrate 100 and the display substrate 300 and a circuit board 700 disposed on the non-display area NDA of the circuit substrate 100.

The first substrate 110 may be a semiconductor circuit substrate. The first substrate 110 is a silicon wafer substrate formed using a semiconductor process, and may include a plurality of pixel circuit parts PXC. Each of the pixel circuit parts PXC may be formed through a process of forming a semiconductor circuit on a silicon wafer. Each of the plurality of pixel circuit parts PXC may include at least one transistor and at least one capacitor formed by the semiconductor process. For example, the plurality of pixel circuit parts PXC may include complementary metal oxide semiconductor (CMOS) circuits.

The plurality of pixel circuit parts PXC may be disposed in the display area DPA and the non-display area NDA. Pixel circuit parts PXC disposed in the display area DPA among the plurality of pixel circuit parts PXC may be electrically connected to corresponding ones of the pixel electrodes AE. A plurality of pixel circuit parts PXC disposed in the display area DPA may be disposed to correspond to a plurality of pixel electrodes AE, and may overlap, the corresponding ones of the light emitting elements ED disposed in the display area DPA, in the third direction DR3, which is the thickness direction.

Pixel circuit parts PXC disposed in the non-display area NDA among the plurality of pixel circuit parts PXC may be electrically connected to corresponding ones of the common electrode connection parts CEP. The plurality of pixel circuit parts PXC disposed in the non-display area NDA may be disposed to correspond to a plurality of common electrode connection parts CEP, and may overlap corresponding ones of the common electrode connection parts CEP and third connection electrodes CNE3 disposed in the non-display area NDA, in the third direction DR3.

The plurality of pixel electrodes AE may be disposed in the display area DPA, and may be disposed on the pixel circuit parts PXC corresponding to the plurality of pixel electrodes AE, respectively. Each of the pixel electrodes AE may be an exposed electrode formed integrally with the pixel circuit part PXC and exposed from the pixel circuit part PXC. The plurality of common electrode connection parts CEP may be disposed in the common electrode areas CPA1, CPA2, and CPA3 of the non-display area NDA, and may be disposed on the pixel circuit parts PXC corresponding to the plurality of common electrode connection parts CEP, respectively. The common electrode connection part CEP may be an exposed electrode formed integrally with the pixel circuit part PXC and exposed from the pixel circuit part PXC. Each of the pixel electrodes AE and the common electrode connection parts CEP may include a metal material such as aluminum (Al).

The plurality of pads PD are disposed in the pad area PDA in the non-display area NDA. The plurality of pads PD are disposed to be spaced apart from the common electrode connection part CEP. The plurality of pads PD may be spaced from the common electrode connection part CEP to the outside of the non-display area NDA. The plurality of pads PD may be electrically connected to corresponding ones of the circuit board pads PDC of the circuit board 700. The plurality of pads PD may be in direct contact with and electrically connected to the circuit board pads PDC. However, the present disclosure is not limited thereto, and the plurality of pads PD may also be electrically connected to the circuit board pads PDC through conducting wires.

The circuit board 700 may be a flexible film such as a flexible printed circuit board (FPCB), a printed circuit board (PCB), a flexible printed circuit (FPC), or a chip on film (COF).

The display substrate 300 may include the plurality of light emitting elements ED, common electrode elements ND, and dummy elements DE, and may be disposed on the display substrate area DSA of the circuit substrate 100. The light emitting elements ED are disposed in the display area DPA of the display substrate 300 so as to correspond to the plurality of pixel electrodes AE of the circuit substrate 100, respectively, and the common electrode elements ND may be disposed in the common electrode areas CPA1, CPA2, and CPA3 of the display substrate 300 so as to correspond to the plurality of common electrode connection parts CEP of the circuit substrate 100, respectively. The dummy elements DE may be disposed in the non-display area NDA of the display substrate 300 so as to overlap an area in which the pixel circuit parts PXC are not formed in the display substrate area DSA of the circuit substrate 100.

Each of the light emitting elements ED, the common electrode elements ND, and the dummy elements DE may be an inorganic light emitting diode element. Each of the light emitting elements ED, the common electrode elements ND, and the dummy elements DE may include a plurality of semiconductor layers SEM1, SEM2, EBL, and SLT, and an active layer MQW. The light emitting elements ED may be electrically connected to the pixel circuit parts PXC of the circuit substrate 100 to emit light from the active layers MQW. The common electrode elements ND may be electrically connected to the pixel circuit parts PXC of the circuit substrate 100, but may not emit light because different semiconductor layers SEM1, SEM2, EBL, and SLT are short-circuited through the third connection electrodes CNE3, and the dummy elements DE may not emit light because they are not electrically connected to the pixel circuit parts PXC.

Each of the light emitting elements ED, the common electrode elements ND, and the dummy elements DE may have a shape extending in the third direction DR3. On behalf of the light emitting elements ED, the common electrode elements ND, and the dummy elements DE, the light emitting element ED will be described by way of example. A length of the light emitting element ED in the third direction DR3 may be greater than a length of the light emitting element ED in a horizontal direction. As an example, the length of the light emitting element ED in the third direction DR3 may be approximately 1 to 5 μm. The light emitting element ED may have a cylindrical shape, a disk shape, or a rod shape with a width greater than a height. However, the present disclosure is not limited thereto, and the light emitting element ED may have a shape such as a rod shape, a wire shape, or a tube shape, or a polygonal prism shape such as a cube shape, a rectangular parallelepiped shape, or a hexagonal prism shape, or may have various shapes such as a shape extending in one direction and having outer surfaces partially inclined.

Each of the light emitting elements ED, the common electrode elements ND, and the dummy elements DE may include a first semiconductor layer SEM1, an electron blocking layer EBL, an active layer MQW, a superlattice layer SLT, and a second semiconductor layer SEM2. The first semiconductor layer SEM1, the electron blocking layer EBL, the active layer MQW, the superlattice layer SLT, and the second semiconductor layer SEM2, may be sequentially stacked along the third direction DR3.

The first semiconductor layer SEM1 may be a p-type semiconductor, and may include a semiconductor material having a chemical formula of AlₓGa_{y}In_{1-x-y}N (0≤x≤1, 0≤y≤1, and 0≤x+y≤1). For example, the semiconductor material may be one or more of AlGaInN, GaN, AlGaN, InGaN, AlN, and InN doped with a p-type dopant. The first semiconductor layer SEM1 may be doped with a p-type dopant, which may be Mg, Zn, Ca, Ba, or the like. For example, the first semiconductor layer SEM1 may be made of p-GaN doped with p-type Mg. The first semiconductor layer SEM1 may have a thickness in a range of 30 nm to 200 nm.

The electron blocking layer EBL may be disposed on the first semiconductor layer SEM1. The electron blocking layer EBL may prevent a phenomenon in which electrons introduced into the active layer MQW are not recombined with holes in the active layer MQW and are injected to other layers. For example, the electron blocking layer EBL may be made of p-AlGaN doped with p-type Mg. A thickness of the electron blocking layer EBL may be in the range of 10 nm to 50 nm, but is not limited thereto. In one or more embodiments, the electron blocking layer EBL may be omitted.

The active layer MQW may be disposed on the electron blocking layer EBL. The active layer MQW may emit light by a recombination of electrons and holes according to light emitting signals applied through the first semiconductor layer SEM1 and the second semiconductor layer SEM2. The active layer MQW may include a material having a single or multiple quantum well structure. When the active layer MQW includes the material having the multiple quantum well structure, the active layer MQW may have a structure in which a plurality of well layers and barrier layers are alternately stacked. In this case, the well layer may be made of InGaN, and the barrier layer may be made of GaN or AlGaN, but the present disclosure is not limited thereto. For example, the active layer MQW may have a structure in which semiconductor materials having large band gap energy and semiconductor materials having small band gap energy are alternately stacked, and may include other Group III to Group V semiconductor materials depending on a wavelength band of emitted light.

The superlattice layer SLT is disposed on the active layer MQW. The superlattice layer SLT may alleviate stress due to a difference in lattice constant between the second semiconductor layer SEM2 and the active layer MQW. For example, the superlattice layer SLT may be made of InGaN or GaN. A thickness of the superlattice layer SLT may be approximately 50 to 200 nm. However, in one or more embodiments, the superlattice layer SLT may be omitted.

The second semiconductor layer SEM2 may be disposed on the superlattice layer SLT. The second semiconductor layer SEM2 may be an n-type semiconductor. The second semiconductor layer SEM2 may include a semiconductor material having a chemical formula of AlₓGa_{y}In_{1-x-y}N (0≤x≤1, 0≤y≤1, and 0≤x+y≤1). For example, the semiconductor material may be one or more of AlGaInN, GaN, AlGaN, InGaN, AlN, and InN doped with an n-type dopant. The second semiconductor layer SEM2 may be doped with an n-type dopant, which may be Si, Ge, Sn, or the like. For example, the second semiconductor layer SEM2 may be made of n-GaN doped with n-type Si. A thickness of the second semiconductor layer SEM2 may be in the range of 500 nm to 1 μm, but is not limited thereto.

According to one or more embodiments, some of the light emitting elements ED of the display device 10 may include different active layers MQW to emit light of different colors. For example, the first light emitting element ED1 may include a first active layer MQW1, the second light emitting element ED2 may include a second active layer MQW2, and the third light emitting element ED3 may include a third active layer MQW3. The first light emitting element ED1 may emit red light, which is light of a first color, the second light emitting element ED2 may emit green light, which is light of a second color, and the third light emitting element ED3 may emit blue light, which is light of a third color. In each of the first light emitting element ED1, the second light emitting element ED2, and the third light emitting element ED3, concentrations of doped dopants in the first semiconductor layers SEM1, the electron blocking layers EBL, the active layers MQW, the superlattice layers SLT, and the second semiconductor layers SEM2 or values of ‘x’ and ‘y’ in the chemical formula of AlₓGa_{y}In_{1-x-y}N (0≤x≤1, 0≤y≤1, and 0≤x+y≤1) may be different from each other. The first to third light emitting elements ED1, ED2, and ED3 may have substantially the same structure and material, but may emit light of different colors due to different component ratios of the semiconductor layers.

For example, the first active layer MQW1 may emit light by a combination of electron-hole pairs according to electrical signals applied through the first semiconductor layer SEM1 and the second semiconductor layer SEM2. The first active layer MQW1 may emit first light having a central wavelength band in the range of approximately 600 nm to 750 nm, that is, light of a red wavelength band.

The second active layer MQW2 may emit light by a combination of electron-hole pairs according to electrical signals applied through the first semiconductor layer SEM1 and the second semiconductor layer SEM2. The second active layer MQW2 may emit second light having a central wavelength band in the range of approximately 480 nm to 560 nm, that is, light of a green wavelength band.

The third active layer MQW3 may emit light by a combination of electron-hole pairs according to electrical signals applied through the first semiconductor layer SEM1 and the second semiconductor layer SEM2. The third active layer MQW3 may emit third light having a central wavelength band in the range of approximately 370 nm to 460 nm, that is, light of a blue wavelength band.

In one or more embodiments in which each of the first active layer MQW1, the second active layer MQW2, and the third active layer MQW3 includes InGaN, a color of light emitted by each of the first active layer MQW1, the second active layer MQW2, and the third active layer MQW3 may be changed depending on a content of indium (In). For example, as the content of indium (In) increases, a wavelength band of the light emitted by the first to third active layers MQW1, MQW2, and MQW3 may move to a red wavelength band, and as the content of indium (In) decreases, a wavelength band of the light emitted by the first to third active layers MQW1, MQW2, and MQW3 may move to a blue wavelength band. The content of indium (In) in the first active layer MQW1 may be higher than that of indium (In) in the second active layer MQW2, and the content of indium (In) in the second active layer MQW2 may be higher than that of indium (In) in the third active layer MQW3. For example, the content of indium (In) in the third active layer MQW3 may be 15%, the content of indium (In) in the second active layer MQW2 may be 25%, and the content of indium (In) in the first active layer MQW1 may be 35% or higher.

Similarly, in one or more embodiments in which each of the first semiconductor layers SEM1, the second semiconductor layers SEM2, the superlattice layers SLT, and the electron blocking layers EBL of the first to third light emitting elements ED1, ED2, and ED3 includes a semiconductor based on GaN, contents of indium (In) or aluminum (Al), concentrations of doped dopants, or the like, in the first semiconductor layers SEM1, the second semiconductor layers SEM2, the superlattice layers SLT, and the electron blocking layers EBL may be different from each other. As in a case of the first to third active layers MQW1, MQW2, and MQW3, contents of indium (In) in the first semiconductor layer SEM1, the second semiconductor layer SEM2, the superlattice layer SLT, and the electron blocking layer EBL of each of the first to third light emitting elements ED1, ED2, and ED3 may be higher or lower than those in the other light emitting elements ED1, ED2, and ED3.

In the display device 10 according to one or more embodiments, the plurality of common electrode elements ND: ND1, ND2, and ND3 and the dummy elements DE: DE1, DE2, and DE3 may have the same structure as the light emitting elements ED and include the same material as the light emitting elements ED. Each of the plurality of common electrode elements ND and dummy elements DE may have a structure in which the first semiconductor layer SEM1, the electron blocking layer EBL, the active layer MQW, the superlattice layer SLT, and the second semiconductor layer SEM2 are sequentially stacked along the third direction DR3, and some of the plurality of common electrode elements ND and dummy elements DE may include active layers MQW1, MQW2, and MQW3 made of different materials.

For example, each of the first common electrode element ND1 and the first dummy element DE1 may have the same structure as the first light emitting element ED1 and include the first active layer MQW1. Each of the second common electrode element ND2 and the second dummy element DE2 may have the same structure as the second light emitting element ED2 and include the second active layer MQW2, and each of the third common electrode element ND3 and the third dummy element DE3 may have the same structure as the third light emitting element ED3 and include the third active layer MQW3.

The insulating layer INS may be around (or surround) side surfaces of the light emitting elements ED and the dummy elements DE, and portions of the insulating layer INS may be disposed on the common electrode layer CEL of the display substrate 300. The insulating layer INS may be entirely disposed on one surface of the common electrode layer CEL opposing (or facing) the first substrate 110, and portions of the insulating layer INS may be then patterned so as not to cover outer surfaces of the common electrode elements ND. In addition, the insulating layer INS may be disposed to partially cover an upper surface of the first semiconductor layer SEM1 in addition to side surfaces of the light emitting elements ED and the dummy elements DE. First connection electrodes CNE1 may be disposed on portions of upper surfaces of the light emitting elements ED on which the insulating layer INS is not disposed.

The first reflective layers RL1 may be disposed on the insulating layer INS and may be around (or surround) the side surfaces of the light emitting elements ED. The first reflective layers RL1 may not be formed in portions of the insulating layer INS disposed on the common electrode layer CEL between the light emitting elements ED. The first reflective layers RL1 may be formed to correspond to the light emitting elements ED, and may be disposed on the side surfaces of the light emitting elements ED and one surface of the first semiconductor layer SEM1.

The second reflective layers RL2 may be disposed on the insulating layer INS and may be around (or surround) the side surfaces of the dummy elements DE. The second reflective layers RL2 may not be formed in portions of the insulating layer INS disposed on the common electrode layer CEL between the dummy elements DE. The second reflective layers RL2 may be formed to correspond to the dummy elements DE, and may be disposed on the side surfaces of the dummy elements DE and one surface of the first semiconductor layer SEM1. Detailed descriptions of the insulating layer INS and the reflective layers RL1 and RL2 are the same as described above.

The display substrate 300 may include the common electrode layer CEL connected to the second semiconductor layers SEM2 of the light emitting elements ED, the common electrode elements ND, and the dummy elements DE as one common layer. The common electrode layer CEL may be disposed over the entire surface of the display substrate 300, and may form a base part of the display substrate 300 together with a base layer BL. The common electrode layer CEL may include sides extending in the first direction DR1 and the second direction DR2, and may be disposed to correspond to the display substrate area DSA of the circuit substrate 100.

The common electrode layer CEL may be an n-type semiconductor including the same material as the second semiconductor layer SEM2. The common electrode layer CEL may include a semiconductor material having a chemical formula of AlₓGa_{y}In_{1-x-y}N (0≤x≤1, 0≤y≤1, and 0≤x+y≤1). For example, the semiconductor material may be one or more of AlGaInN, GaN, AlGaN, InGaN, AlN, and InN doped with an n-type dopant. The common electrode layer CEL may be doped with an n-type dopant, which may be Si, Ge, Sn, or the like. For example, the common electrode layer CEL may be made of n-GaN doped with n-type Si.

It has been illustrated in the drawings that the common electrode layer CEL includes the same material as the second semiconductor layers SEM2 to be integrated with the second semiconductor layers SEM2, but the present disclosure is not limited thereto. In one or more embodiments, the common electrode layer CEL may include a material different from that of the second semiconductor layers SEM2 to be disposed as a separate layer from the second semiconductor layers SEM2. The common electrode layer CEL may also be electrically connected to the second semiconductor layers SEM2 without being integrated with the second semiconductor layers SEM2.

The base layer BL is disposed on the common electrode layer CEL. The base layer BL may be an undoped semiconductor. The base layer BL may include a material that is the same as that of the second semiconductor SEM2, but is not doped with an n-type or p-type dopant. In one or more embodiments, the base layer BL may be made of at least one of undoped InAlGaN, GaN, AlGaN, InGaN, AlN, and InN, but is not limited thereto. The common electrode layer CEL and the base layer BL may cover the display area DPA and the non-display area NDA of the display substrate 300.

The base layer BL may be a non-conductive layer that includes a material similar to that of the light emitting elements ED and the common electrode layer CEL, but is not doped with a dopant. The base layer BL is disposed on the common electrode layer CEL, but is not electrically connected to the common electrode layer CEL, and may function as an insulating film in the display substrate 300.

Connection electrodes CNE: CNE1, CNE2, and CNE3 may be disposed between the light emitting elements ED and the common electrode elements ND, and the circuit substrate 100. The connection electrodes CNE1, CNE2, and CNE3 may include the first connection electrodes CNE1 and the second connection electrodes CNE2 disposed between the light emitting elements ED and the pixel electrodes AE and the third connection electrodes CNE3 disposed between the common electrode elements ND and the common electrode connection parts CEP.

The first connection electrodes CNE1 and the second connection electrodes CNE2 may be disposed to correspond to the light emitting elements ED and the pixel electrodes AE in the display area DPA. The first connection electrodes CNE1 may be disposed on one surfaces of the first semiconductor layers SEM1 of the light emitting elements ED, and the second connection electrodes CNE2 may be disposed between the first connection electrodes CNE1 and the pixel electrodes AE.

The first connection electrode CNE1 may be electrically connected to the second connection electrode CNE2 and the pixel electrode AE to transfer a light emitting signal applied to the pixel electrode AE to the light emitting element ED. The first connection electrode CNE1 may be an ohmic connection electrode. However, the present disclosure is not limited thereto, and the first connection electrode CNE1 may also be a Schottky connection electrode. A width of the first connection electrode CNE1 may be smaller than that of the light emitting element ED. The first connection electrode CNE1 may be disposed on only a portion of one surface of the first semiconductor layer SEM1, and the insulating layer INS may be disposed on the other portion on one surface of the first semiconductor layer SEM1.

The first connection electrode CNE1 may decrease resistance due to a contact between the light emitting element ED and the second connection electrode CNE2 when the light emitting element ED is electrically connected to the second connection electrode CNE2. The first connection electrode CNE1 may include a conductive metal. For example, the first connection electrode CNE1 may include at least one of gold (Au), copper (Cu), tin (Sn), titanium (Ti), aluminum (Al), and silver (Ag). Alternatively, the first connection electrode CNE1 may include a transparent conductive material such as indium tin oxide (ITO) or indium zinc oxide (IZO). As an example, the first connection electrode CNE1 may include an alloy of gold and tin between which a ratio is 9:1, 8:2, or 7:3, or include an alloy (SAC305) of copper, silver, and tin. It has been illustrated in the drawings that the first connection electrode CNE1 has a single-layer structure, but the present disclosure is not limited thereto. The first connection electrode CNE1 may have a multilayer structure in which two or more layers including the above-described material are stacked.

The second connection electrode CNE2 may be disposed directly on and may be in contact with the pixel electrode AE. The second connection electrodes CNE2 may serve as a bonding metal for bonding the pixel electrodes AE and the light emitting element ED to each other in a fabrication process. The second connection electrodes CNE2 may include a material that may be electrically connected to the pixel electrodes AE and the light emitting elements ED. For example, the second connection electrode CNE2 may include at least one of gold (Au), copper (Cu), aluminum (Al), and tin (Sn) or include transparent conductive oxide such as indium tin oxide (ITO) or indium zinc oxide (IZO). Alternatively, the second connection electrode CNE2 may include a first layer including any one of gold (Au), copper (Cu), aluminum (Al), and tin (Sn) and a second layer including another of gold (Au), copper (Cu), aluminum (Al), and tin (Sn).

The third connection electrodes CNE3 may be disposed to cover the common electrode elements ND. Each of a plurality of third connection electrodes CNE3 may have a shape extending in one direction, and may be disposed in each of the common electrode areas CPA1, CPA2, and CPA3. Because the insulating layer INS is not disposed on the outer surfaces of the common electrode elements ND, the third connection electrodes CNE3 may be in direct contact with the plurality of semiconductor layers of the common electrode elements ND. As an example, one third connection electrode CNE3 may be disposed in the common electrode area CPA1, CPA2, or CPA3 to cover the outer surfaces of the plurality of common electrode elements ND. However, the present disclosure is not limited thereto. In one or more embodiments, the third connection electrodes CNE3 may be disposed to correspond to the common electrode elements ND, respectively, and different third connection electrodes CNE3 disposed in the same common electrode area CPA1, CPA2, or CPA3 may be disposed to be spaced from each other.

In one or more embodiments, the third connection electrode CNE3 may include at least one of gold (Au), copper (Cu), tin (Sn), titanium (Ti), aluminum (Al), and silver (Ag). Alternatively, the third connection electrode CNE3 may include a transparent conductive material such as indium tin oxide (ITO) or indium zinc oxide (IZO). The third connection electrode CNE3 may or may not include the same material as that of the first connection electrode CNE1 and the second connection electrode CNE2.

In one or more embodiments, a thickness of portions of the third connection electrodes CNE3 disposed on upper surfaces of the common electrode elements ND may be the same as the sum of thicknesses of the first connection electrode CNE1 and the second connection electrode CNE2. The third connection electrode CNE3 may have a thickness enough for a height of a portion between the light emitting element ED and the common electrode layer CEL to become equal to a height of the first connection electrode CNE1 and the second connection electrode CNE2 disposed on the light emitting element ED on the basis of one surface of the common electrode layer CEL. In the display substrate 300, the display area DPA and the common electrode areas CPA1, CPA2, and CPA3 may have substantially the same height from one surface of the common electrode layer CEL. On the other hand, other members are not disposed on the dummy elements DE of the non-display area NDA, and thus, the non-display area NDA may have a height lower than that of the display area DPA and the common electrode areas CPA1, CPA2, and CPA3.

The third connection electrode CNE3 may be disposed directly on and in contact with the common electrode connection part CEP. The third connection electrode CNE3 may be electrically connected to the common electrode connection part CEP. In one or more other embodiments, the third connection electrode CNE3 may be electrically connected to any one of the pads PD through the pixel circuit part PXC disposed in the non-display area NDA.

The third connection electrode CNE3 may include a material that may be electrically connected to the common electrode connection part CEP. For example, the third connection electrode CNE3 may include at least one of gold (Au), copper (Cu), aluminum (Al), and tin (Sn). Alternatively, the third connection electrode CNE3 may include a first layer including any one of gold (Au), copper (Cu), aluminum (Al), and tin (Sn) and a second layer including another of gold (Au), copper (Cu), aluminum (Al), and tin (Sn).

The filling layer 500 may be disposed between the circuit substrate 100 and the display substrate 300. The filling layer 500 may fill a space formed between the first substrate 110 and the common electrode layer CLE by steps between the pixel electrodes AE and the common electrode connection parts CEP of the circuit substrate 100 and the light emitting elements ED, the common electrode elements ND, and the dummy elements DE of the display substrate 300. The filling layer 500 may include an insulating material such as silicon oxide (SiOₓ), silicon nitride (SiNₓ), or silicon oxynitride (SiOₓN_{y}), but is not limited thereto. It has been illustrated in the drawings that the filling layer 500 is formed as one layer to completely fill a space between the common electrode layer CEL and the first substrate 110. The filling layer 500 may be made of a material having fluidity when the display substrate 300 and the circuit substrate 100 are bonded to each other, may be disposed between the display substrate 300 and the circuit substrate 100 and may fill a space between the display substrate 300 and the circuit substrate 100. However, the present disclosure is not limited thereto. In one or more embodiments, the filling layer 500 may be disposed so that surfaces of the circuit substrate 100 and the display substrate 300 bonded to each other are planarized. For example, a first filling layer may be disposed on the first substrate 110 of the circuit substrate 100 and a second filling layer may be disposed on the common electrode layer CEL of the display substrate 300 to planarize upper surfaces of the first substrate 110 and the common electrode layer CEL. In this case, in the display device 10, a physical boundary may remain between the first filling layer and the second filling layer at a portion where the circuit substrate 100 and the display substrate 300 are bonded to each other.

According to one or more embodiments, in the display device 10, the second semiconductor layers SEM2 of the light emitting elements ED, the common electrode elements ND, and the dummy elements DE may be electrically connected to each other. For example, the common electrode layer CEL may include the same material as the second semiconductor layers SEM2, and each of the second semiconductor layers SEM2 of the light emitting elements ED, the common electrode elements ND, and the dummy elements DE may be integrated with the common electrode layer CEL. In the display substrate 300, a plurality of second semiconductor layers SEM2 may partially protrude from the common electrode layer CEL to form patterns spaced apart from each other.

It has been illustrated in the drawings that the common electrode layer CEL is integrated with the second semiconductor layers SEM2, but the present disclosure is not limited thereto. As described above, the common electrode layer CEL may include a material different from that of the second semiconductor layers SEM2 to be electrically connected to the second semiconductor layers SEM2 without being integrated with the second semiconductor layers SEM2.

The common electrode layer CEL may be electrically connected to the third connection electrodes CNE3 disposed on the common electrode elements ND, and may be electrically connected to the common electrode connection parts CEP of the circuit substrate 100. The insulating layer INS may not be disposed on the common electrode areas CPA1, CPA2, and CPA3 of one surface of the common electrode layer CEL, and the third connection electrodes CNE3 may be disposed directly on corresponding portions. The common electrode layer CEL may be electrically connected to the second semiconductor layers SEM2 of the light emitting elements ED in the display area DPA, and may be electrically connected to the second semiconductor layers SEM2 of the common electrode elements ND and the third connection electrodes CNE3 in the common electrode areas CPA1, CPA2, and CPA3. The common electrode layer CEL may be electrically connected to the second semiconductor layers SEM2 of the dummy elements DE in the non-display area NDA.

The second semiconductor layers SEM2 of the light emitting elements ED, the common electrode elements ND, and the dummy elements DE may be electrically connected to the common electrode layer CEL in common, but the first semiconductor layers SEM1 of only the light emitting elements ED may be electrically connected to the pixel circuit parts PXC of the circuit substrate 100. For example, one ends of the plurality of light emitting elements ED may be electrically connected to the pixel electrodes AE of the circuit substrate 100 through the first connection electrodes CNE1 and the second connection electrodes CNE2. The other ends of the light emitting elements ED may be electrically connected to the common electrode connection parts CEP of the circuit substrate 100 through the common electrode layer CEL and the third connection electrodes CNE3. The light emitting elements ED may have both ends electrically connected to the pixel circuit parts PXC of the circuit substrate 100, and may receive electrical signals transferred from the pixel circuit parts PXC to emit light from the active layers MQW. The first light emitting element ED1 may include the first active layer MQW1 to emit the red light, which is the light of the first color, the second light emitting element ED2 may include the second active layer MQW2 to emit the green light, which is the light of the second color, and the third light emitting element ED3 may include the third active layer MQW3 to emit the blue light, which is the light of the third color.

Alternatively, the common electrode elements ND and the dummy elements DE may not be electrically connected to the pixel circuit parts PXC of the circuit substrate 100 or may not emit light because both ends of the common electrode elements ND and the dummy elements DE are short-circuited even though the common electrode elements ND and the dummy elements DE are connected to the pixel circuit parts PXC of the circuit substrate 100.

For example, both ends of the outer surfaces of the common electrode elements ND may be short-circuited by the third connection electrodes CNE3. The third connection electrode CNE3 may be disposed on at least a portion of a side surface of the common electrode element ND and may be in contact with at least the first semiconductor layer SEM1 and the second semiconductor layer SEM2. At least a portion of the third connection electrode CNE3 may be in direct contact with each of a side surface of the first semiconductor layer SEM1 and a side surface of the second semiconductor layer SEM2. It has been illustrated in the drawings that the third connection electrode CNE3 completely covers the outer surface of the common electrode element ND, but the present disclosure is not limited thereto. In one or more embodiments, the third connection electrode CNE3 may be disposed to be in contact with only the first semiconductor layer SEM1 and the second semiconductor layer SEM2 of the common electrode element ND. In the common electrode element ND, the first semiconductor layer SEM1 and the second semiconductor layer SEM2 are short-circuited, such that electrical signals applied from the common electrode connection part CEP and the common electrode layer CEL may not flow to the active layer MQW of the common electrode element ND. Accordingly, light may not be emitted from the common electrode element ND. The common electrode layer CEL may serve as a common electrode of the light emitting elements ED, and the common electrode elements ND may serve as electrodes connecting the common electrode layer CEL and the common electrode connection parts CEP of the circuit substrate 100 to each other together with the third connection electrodes CNE3.

One ends of the dummy elements DE are not electrically connected to the pixel circuit parts PXC of the circuit substrate 100, and thus, the dummy elements DE may not emit light. Similar to the light emitting elements ED, the second semiconductor layers SEM2 of the dummy elements DE may be electrically connected to the common electrode layer CEL. The second semiconductor layers SEM2 of the dummy elements DE may be electrically connected to the common electrode connection parts CEP through the common electrode layer CEL and the third connection electrodes CNE3, and the first semiconductor layers SEM1 of the dummy elements DE may not be electrically connected to the pixel circuit parts PXC. Unlike the light emitting elements ED, each of the side surfaces of the dummy elements DE and one surfaces of the first semiconductor layers SEM1 of the dummy elements DE may be covered by the insulating layer INS. The first connection electrode CNE1 may not be disposed on one surface of the first semiconductor layer SEM1 of the dummy element DE, one surface of the first semiconductor layer SEM1 of the dummy element DE may be covered by the insulating layer INS, and neither the pixel electrode AE nor the first and second connection electrodes CNE1 and CNE2 may be disposed between the dummy element DE and the first substrate 110. Accordingly, the light may not be emitted from the dummy element DE.

In the display device 10, elements having substantially the same structure may be disposed in the display substrate 300 regardless of the display area DPA and the non-display area NDA. As described above, each of the light emitting elements ED of the display area DPA, the common electrode elements ND of the common electrode areas CPA1, CPA2, and CPA3, and the dummy element DE of the non-display area NDA may have a structure in which the first semiconductor layer SEM1, the electron blocking layer EBL, the active layer MQW, the superlattice layer SLT, and the second semiconductor layer SEM2 are stacked along the third direction DR3, and may include a different active layer MQW1, MQW2, or MQW3. However, both ends of only the light emitting elements ED disposed in the display area DPA may be electrically connected to the circuit substrate 100 to emit the light. The common electrode elements ND and the dummy elements DE disposed in areas other than the display area DPA may not emit the light.

In processes for fabrication of the display device 10, the light emitting elements ED disposed in the display substrate 300 may be formed on the common electrode layer CEL together with the common electrode elements ND and the dummy elements DE. In the display device 10, the semiconductor layers are uniformly formed over the entire surface of the common electrode layer CEL in the display substrate 300, and thus, elements having a uniform quality and density may be formed in at least the display area DPA on the common electrode layer CEL. Accordingly, in the display device 10, the elements formed in the display area DPA may be selected and formed as the light emitting element ED, and the elements formed in the areas other than the display area DPA may remain as the common electrode elements ND or the dummy elements DE. In the display device 10 according to embodiments, the light emitting elements ED emitting the light may have a uniform quality and density between a central portion of the display area DPA and an area adjacent to a boundary with the non-display area NDA, and a display quality may be improved.

Hereinafter, processes for fabrication of the display device 10 will be described with further reference to other drawings.

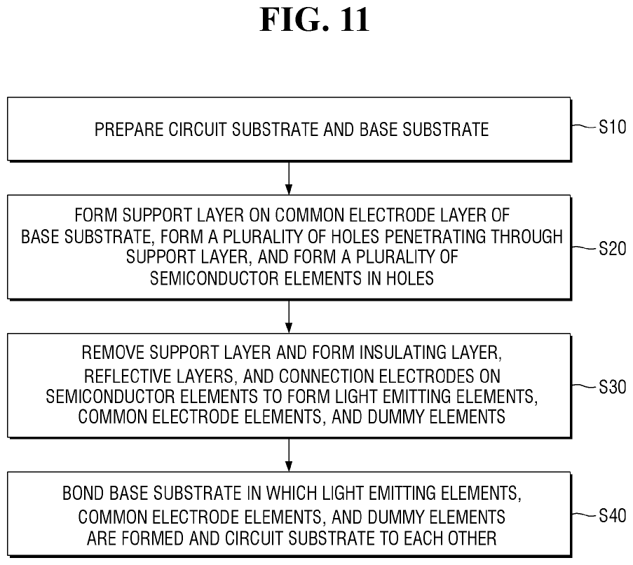

FIG. 11 is a flowchart illustrating a method for fabrication of the display device according to one or more embodiments.

Referring to FIG. 11, a method for fabrication of the display device 10 according to one or more embodiments may include preparing a circuit substrate 100 and a base substrate SUB (S10); forming a support layer SPL on a common electrode layer CEL of the base substrate SUB, forming a plurality of holes H1, H2, and H3 penetrating through the support layer SPL, and forming a plurality of semiconductor elements SCE1, SCE2, and SCE3 in the plurality of holes H3, H2, and H1, respectively (S20); removing the support layer SPL and forming an insulating layer INS, reflective layers RL1 and RL2, and connection electrodes CNE1, CNE2, and CNE3 on the plurality of semiconductor elements to form a plurality of light emitting elements ED, common electrode elements ND, and dummy elements DE (S30); and bonding the base substrate SUB in which the light emitting elements ED, the common electrode elements ND, and the dummy elements DE are formed and circuit substrate 100 to each other (S40).

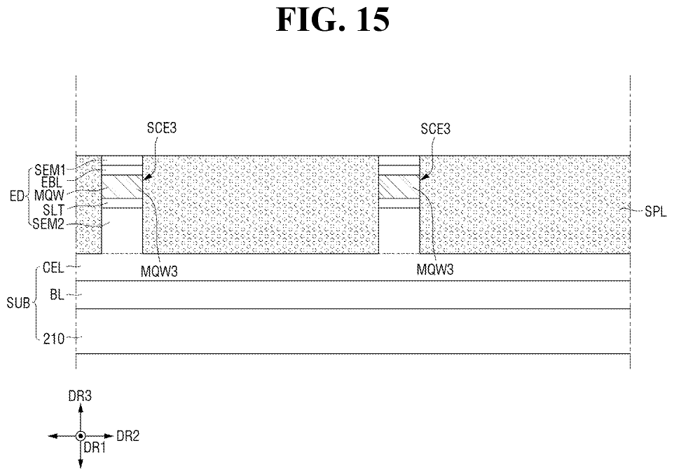

The method for fabrication of the display device 10 may include a process of preparing each of the circuit substrate 100 and the display substrate 300 and then bonding the circuit substrate 100 and the display substrate 300 to each other. In a process for fabrication of the display substrate 300, a process of preparing the base substrate SUB including a base layer BL and the common electrode layer CEL and forming the plurality of light emitting elements ED, common electrode elements ND, and the dummy elements DE on the base substrate SUB may be performed. Semiconductor elements SCE (see FIG. 15) may be entirely formed on the common electrode layer CEL, some of the semiconductor elements SCE may become the light emitting elements ED, and the others of the semiconductor elements SCE may become the common electrode elements ND and the dummy elements DE. Because the semiconductor elements SCE1, SCE2, and SCE3 are entirely formed regardless of areas of the common electrode layer CEL, the light emitting elements ED formed in the display area DPA in the common electrode layer CEL may have a uniform quality and density regardless of positions. Hereinafter, a method for fabrication of the display device 10 will be described in detail with further reference to other drawings.

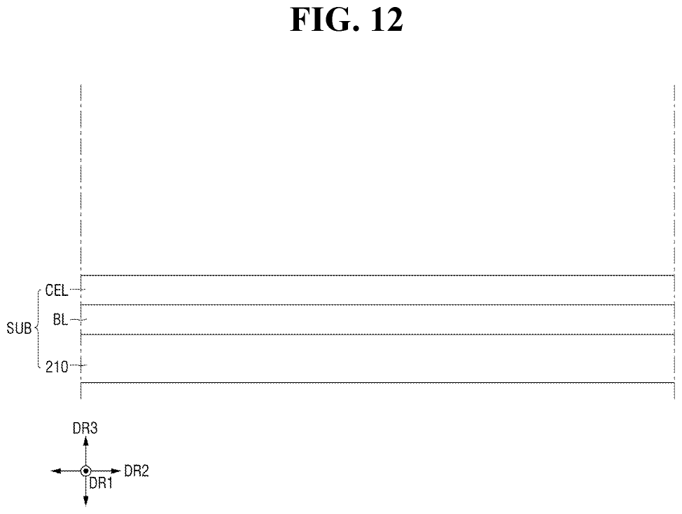

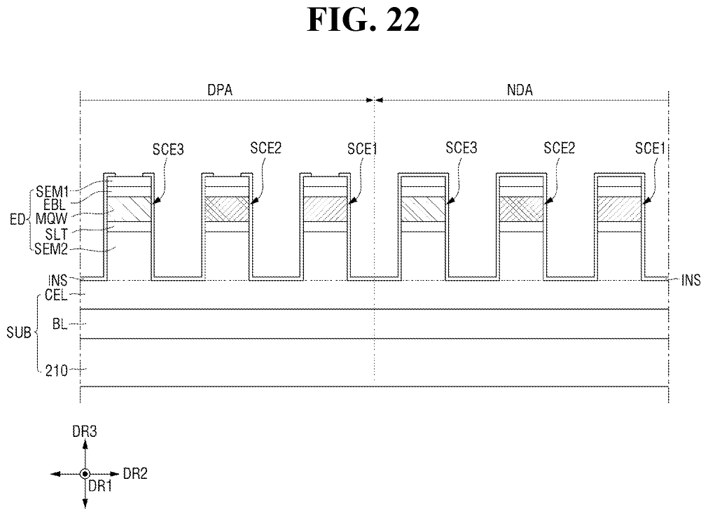

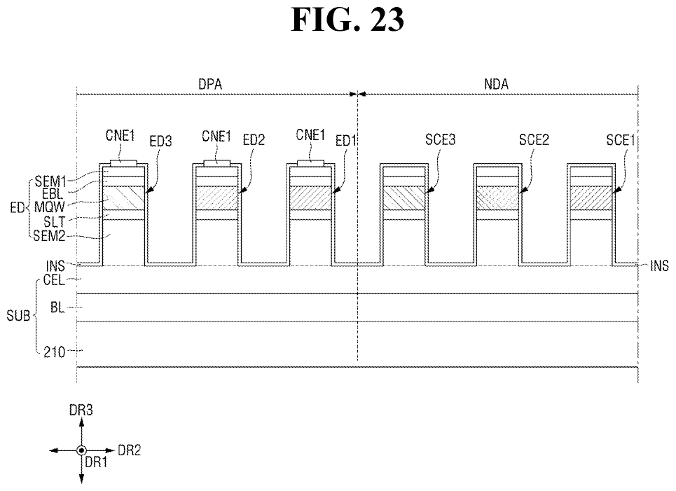

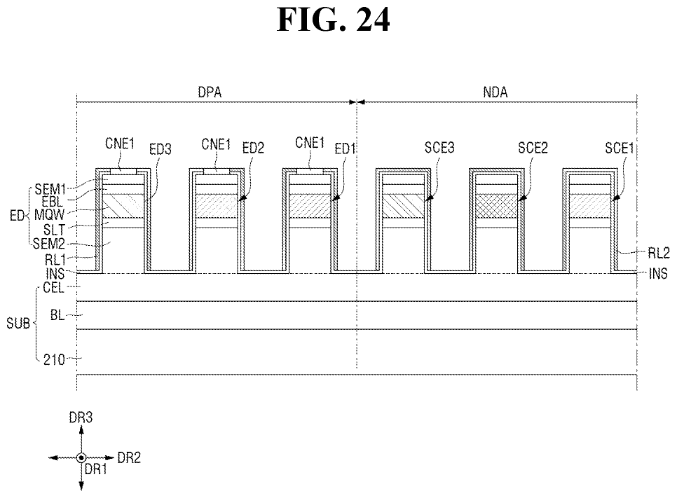

FIGS. 12 to 28 are cross-sectional views sequentially illustrating processes for fabrication of the display device according to an embodiment. FIGS. 12 to 28 sequentially illustrate processes for fabrication of the display device 10 on the basis of one cross section of the display device 10 illustrated in FIG. 8.

First, referring to FIG. 12, the circuit substrate 100 and the base substrate SUB for forming the display substrate 300 are prepared (S10). The circuit substrate 100 includes a first substrate 110 including pixel circuit parts PXC, and pixel electrodes AE and common electrode connection parts CEP formed on one surface of the first substrate 110 (e.g., see FIG. 8). A description for a structure of the circuit substrate 100 is the same as described above.

The base substrate SUB includes a second substrate 210, a base layer BL disposed on the second substrate 210, and a common electrode layer CEL disposed on the base layer BL. The second substrate 210 may be a sapphire substrate (A1203) or a silicon wafer including silicon. However, the present disclosure is not limited thereto, and the second substrate 210 may also be a semiconductor substrate such as a GaAs substrate. Hereinafter, a case where the second substrate 210 is the sapphire substrate will be described by way of example.

The base layer BL and the common electrode layer CEL disposed on the second substrate 210 are the same as described above. The common electrode layer CEL may be an n-type semiconductor, and the base layer BL may include an undoped semiconductor and may be made of a material that is not doped with an n-type or p-type dopant. In one or more embodiments, for example, the common electrode layer CEL may be made of one or more of AlGaInN, GaN, AlGaN, InGaN, AlN, and InN doped with an n-type dopant. The base layer BL may be made of at least one of undoped InAlGaN, GaN, AlGaN, InGaN, AlN, and InN, but is not limited thereto. It has been illustrated in FIG. 12 that one base layer BL is stacked, but the disclosure is not limited thereto, and a plurality of base layers BL may also be formed. The base layer BL may be disposed to decrease a difference in lattice constant between the common electrode layer CEL and the second substrate 210.

The base layer BL and the common electrode layer CEL may be formed together with semiconductor layers to be described later through an epitaxial growth method. The epitaxial growth method may be electron beam deposition, physical vapor deposition (PVD), chemical vapor deposition (CVD), plasma laser deposition (PLD), dual-type thermal evaporation, sputtering, metal organic chemical vapor deposition (MOCVD), or the like. As an example, the base layer BL and the common electrode layer CEL may be formed by the metal organic chemical vapor deposition (MOCVD), but are not limited thereto.

A precursor material for forming a plurality of semiconductor material layers is not particularly limited within a range that may be generally selected for forming a target material. As an example, the precursor material may be a metal precursor including an alkyl group such as a methyl group or an ethyl group. For example, the precursor material may be a compound such as trimethyl gallium (Ga(CH₃)₃), trimethyl aluminum (Al(CH₃)₃), or triethyl phosphate ((C₂H₅)₃PO₄), but is not limited thereto.

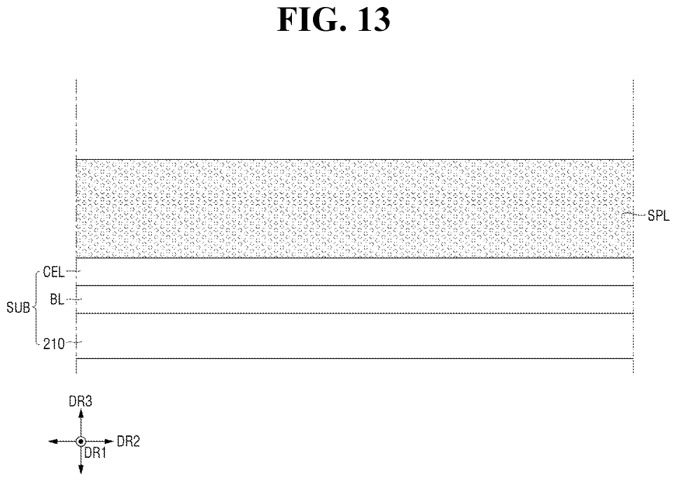

Next, referring to FIGS. 13 to 20, the support layer SPL is formed on the common electrode layer CEL of the base substrate SUB, the plurality of holes H1, H2, and H3 penetrating through the support layer SPL are formed, and the plurality of semiconductor elements SCE1, SCE2, and SCE3 are formed in the holes H1, H2, and H3 (S20). The semiconductor elements SCE1, SCE2, and SCE3 formed in the holes H1, H2, and H3 are formed on the common electrode layer CEL exposed by the holes H1, H2 and H3, respectively, and may form light emitting elements ED, common electrode elements ND, and dummy elements DE in a subsequent process.

The support layer SPL may be entirely disposed on the common electrode layer CEL. The support layer SPL may include an insulating material such as silicon oxide (SiOₓ), silicon nitride (SiNₓ), or silicon oxynitride (SiOₓN_{y}), and function as a mask in a process for forming the semiconductor elements SCE1, SCE2, and SCE3.

When the support layer SPL is disposed, the plurality of holes H1, H2, and H3 penetrating through the support layer SPL are formed, and the semiconductor elements SCE1, SCE2, and SCE3 are formed in the holes H3, H2, and H1, respectively. As described above, each of the light emitting elements ED, the common electrode elements ND, and the dummy elements DE includes active layers MQW1, MQW2, and MQW3 partially made of different materials. A process of forming the semiconductor elements SCE1, SCE2, and SCE3 may be performed as a process of concurrently (or simultaneously) forming elements including active layers MQW1, MQW2, and MQW3 made of the same material and forming elements including active layers MQW1, MQW2, and MQW3 made of different materials by another process.

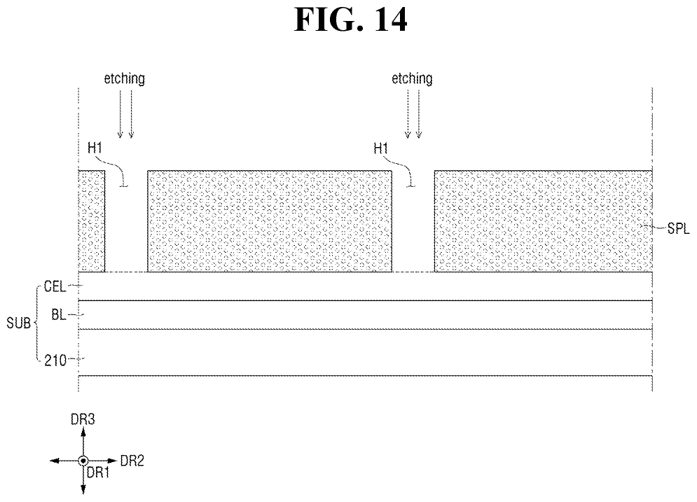

First, third semiconductor elements SCE3 including third active layers MQW3 emitting blue light, which is light of a third color, are formed. As illustrated in FIGS. 14 and 15, a plurality of first holes H1 penetrating through the support layer SPL are formed by etching portions of the support layer SPL, and a plurality of third semiconductor elements SCE3 are formed in the first holes H1, respectively. The plurality of first holes H1 are formed to be spaced from each other. An interval between the first holes H1 spaced from each other, a width of the first holes H1, and the like, may be set according to layouts and sizes of the light emitting elements ED, the common electrode elements ND, and the dummy elements DE disposed in the display substrate 300. That is, the width of the first holes H1 and the interval between the first holes H1 may be the same as a width of elements including the third active layers MQW3 among the light emitting elements ED, the common electrode elements ND, and the dummy elements DE and an interval between these elements.

The process of forming the semiconductor elements SCE1, SCE2, and SCE3 may be performed through an epitaxial growth method as in the process of forming the base layer BL and the common electrode layer CEL. When an upper surface of the common electrode layer CEL is exposed by the first holes H1, a precursor material is injected onto the common electrode layer CEL to grow semiconductor crystals. Second semiconductor layers SEM2 disposed on the common electrode layer CEL may include substantially the same material as the common electrode layer CEL, and may be formed by growing the semiconductor crystals of the common electrode layer CEL. Accordingly, the second semiconductor layers SEM2 may be formed integrally with the common electrode layer CEL.

Then, superlattice layers SLT, third active layers MQW3, electron blocking layers EBL, and first semiconductor layers SEM1 are sequentially grown to form the third semiconductor elements SCE3. In the process, only the third semiconductor elements SCE3 having the third active layers MQW3 are formed, and in subsequent repeated processes, semiconductor elements SCE1 and SCE2 including second active layers MQW2 or first active layers MQW1 may be formed.

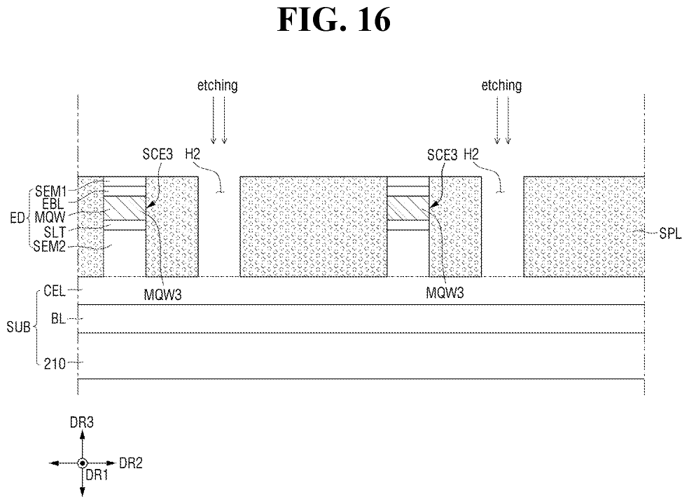

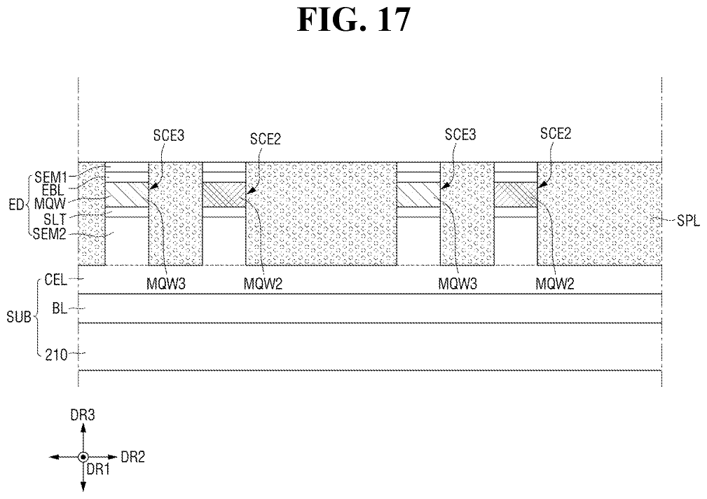

As illustrated in FIGS. 16 and 17, a plurality of second holes H2 penetrating through the support layer SPL are formed by etching portions of the support layer SPL, and second semiconductor elements SCE2 including second active layers MQW2 emitting green light, which is light of a second color, are formed in the second holes H2, respectively. The plurality of second holes H2 are formed to be spaced from each other. A width of the second holes H2 and an interval between the second holes H2 that are spaced from each other may be the same as a width of elements including the second active layers MQW2 among the light emitting elements ED, the common electrode elements ND, and the dummy elements DE and an interval between these elements. Second semiconductor layers SEM2, superlattice layers SLT, second active layers MQW2, electron blocking layers EBL, and first semiconductor layers SEM1 are sequentially grown on the common electrode layer CEL exposed by the second holes H2 to form the second semiconductor elements SCE2.

A process of forming the second semiconductor elements SCE2 may be performed using a precursor material different from that in the process of forming the third semiconductor elements SCE3 and under a process condition different from that in the process of forming the third semiconductor elements SCE3. The second semiconductor elements SCE2 and the third semiconductor elements SCE3 may include the second active layers MQW2 and the third active layers MQW3, respectively, and may have different concentrations of dopant, contents of indium (In), and the like, as described above. In the processes for fabrication of the display device 10, the same processes of forming the semiconductor elements SCE1, SCE2, and SCE3 may be repeated, but process conditions in each process may be partially different from each other.

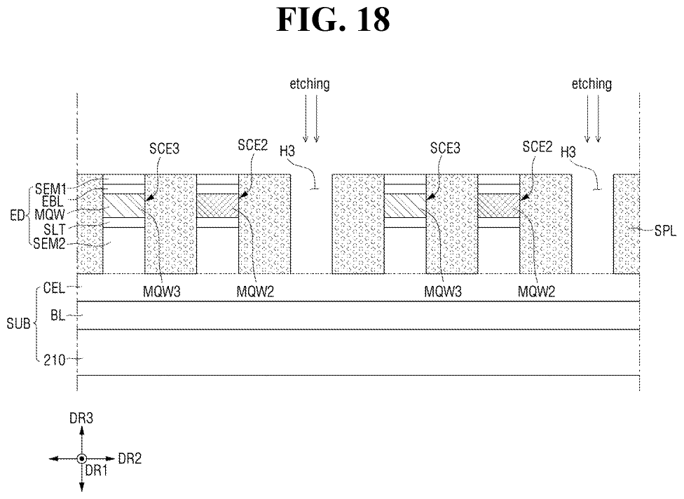

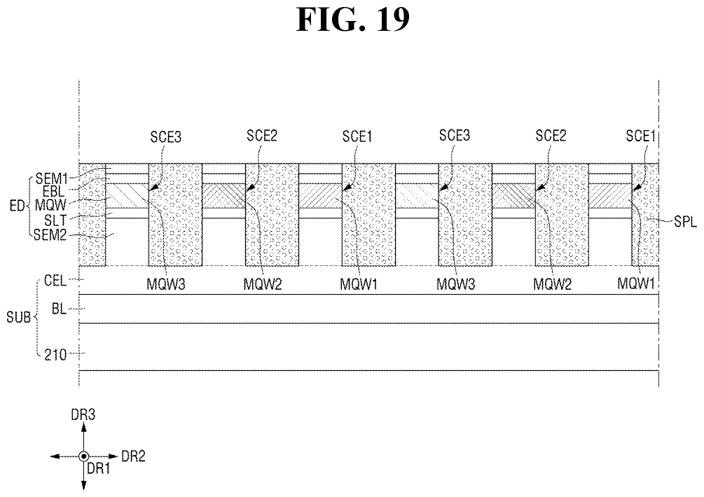

Next, as illustrated in FIGS. 18 and 19, a plurality of third holes H3 penetrating through the support layer SPL are formed by etching portions of the support layer SPL, and first semiconductor elements SCE1 including first active layers MQW1 emitting red light, which is light of a first color, are formed in the third holes H3, respectively. The plurality of third holes H3 are formed to be spaced from each other. A width of the third holes H3 and an interval between the third holes H3 spaced from each other may be the same as a width of elements including the first active layers MQW1 among the light emitting elements ED, the common electrode elements ND, and the dummy elements DE and an interval between these elements. Second semiconductor layers SEM2, superlattice layers SLT, first active layers MQW1, electron blocking layers EBL, and first semiconductor layers SEM1 are sequentially grown on the common electrode layer CEL exposed by the third holes H3 to form the first semiconductor elements SCE1. A process of forming the first semiconductor elements SCE1 may be different from each of the processes of forming the second semiconductor elements SCE2 and the third semiconductor elements SCE3.

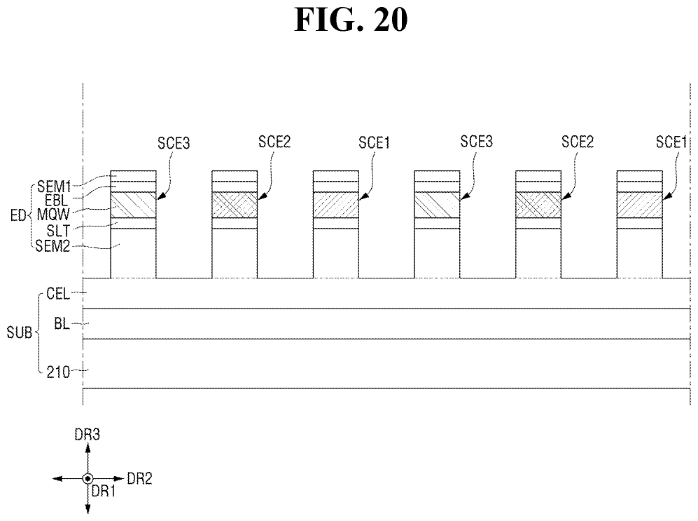

Then, as illustrated in FIG. 20, the support layer SPL may be removed to form the plurality of semiconductor elements SCE1, SCE2, and SCE3 on the common electrode layer CEL.

In such a process, each of the semiconductor elements SCE1, SCE2, and SCE3 is formed by an epitaxial growth method. The epitaxial growth method is performed in a manner of injecting a precursor material to grow semiconductor crystals, but when the semiconductor elements SCE1, SCE2, and SCE3 are formed only in a specific area, for example, the display area DPA, on the common electrode layer CEL, if a precursor material is injected only into the specific area, differences in quality and density between the semiconductor elements SCE1, SCE2, and SCE3 may occur according to positions in each area. In this case, the precursor material is not injected onto an entire surface of the common electrode layer CEL, and thus, a difference may occur in a concentration of the injected precursor material between a central portion and an outer side portion of the specific area, which may cause differences in quality and concentration of the formed semiconductor elements SCE1, SCE2, and SCE3. On the other hand, in the method for fabrication of the display device 10 according to one or more embodiments, the semiconductor elements SCE1, SCE2, and SCE3 are entirely formed on the common electrode layer CEL regardless of positions, and the light emitting elements ED are then formed using only semiconductor elements SCE1, SCE2, and SCE3 disposed in a partial area among the semiconductor elements SCE1, SCE2, and SCE3. Accordingly, when the semiconductor elements SCE1, SCE2, and SCE3 formed in an area having a relatively uniform quality and concentration are selected, a quality of the light emitting elements ED disposed in the display substrate 300 may be uniform.

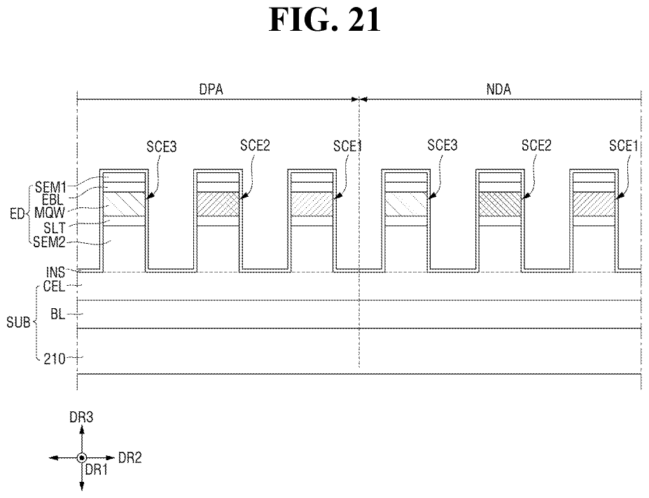

Next, referring to FIGS. 21 to 26, the insulating layer INS, the reflective layers RL1 and RL2, and the connection electrodes CNE1, CNE2, and CNE3 are formed on the semiconductor elements SCE1, SCE2, and SCE3 to form the light emitting elements ED, the common electrode elements ND, and the dummy elements DE (S30). The light emitting elements ED may have the first connection electrodes CNE1 and the second connection electrodes CNE2 disposed on the first semiconductor layers SEM1 thereof, the common electrode elements ND may be covered by third connection electrodes CNE3, and the dummy elements DE may be completely covered by the insulating layer INS. In the process, by configuring layers disposed on the semiconductor elements SCE1, SCE2, and SCE3 so as to be different from each other according to specific areas on the common electrode layer CEL, the semiconductor elements SCE1, SCE2, and SCE3 may be divided into the light emitting elements ED, the common electrode elements ND, and the dummy elements DE.

First, as illustrated in FIGS. 21 to 24, the insulating layer INS, the first connection electrodes CNE1, and the reflective layers RL1 and RL2 are formed on the semiconductor elements SCE1, SCE2, and SCE3 to form the light emitting elements ED. The insulating layer INS is entirely disposed on the common electrode layer CEL, and is formed to cover the plurality of semiconductor elements SCE1, SCE2, and SCE3. The insulating layer INS may be formed through a deposition process, a sputtering process, an atomic layer deposition process, or the like, rather than the epitaxial growth method, unlike the semiconductor layers.

Then, portions of the insulating layer INS are removed so that portions of upper surfaces of semiconductor elements SCE1, SCE2, and SCE3 disposed in the display area DPA among the semiconductor elements SCE1, SCE2, and SCE3 covered by the insulating layer INS are exposed. A process of removing portions of the insulating layer INS may be performed through an etching process using a mask. The etching process is a general etching process for material layers, and may be, for example, dry etching, wet etching, reactive ion etching (RIE), deep reactive ion etching (DRIE), inductively coupled plasma reactive ion etching (ICP-RIE), or the like. In a case of the dry etching, anisotropic etching is possible, and the dry etching may thus be suitable for vertical etching. When the above-described etching method is used, an etchant may be Cl₂, O₂, or the like. However, the present disclosure is not limited thereto.

As illustrated in the drawing, first to third semiconductor elements SCE1, SCE2, and SCE3 disposed on the left side are semiconductor elements SCE1, SCE2, and SCE3 disposed in the display area DPA, respectively, and portions of upper surfaces of first semiconductor layers SEM1 of the first to third semiconductor elements SCE1, SCE2, and SCE3 disposed on the left side (e.g., the display area DPA) may be exposed. First to third semiconductor elements SCE1, SCE2, and SCE3 disposed on the right side are semiconductor elements SCE1, SCE2, and SCE3 disposed in the non-display area NDA, respectively, and upper surfaces of first semiconductor layers SEM1 of the first to third semiconductor elements SCE1, SCE2, and SCE3 disposed on the right side (e.g., the non-display area NDA) may not be exposed.

Then, the first connection electrodes CNE1 are formed respectively on upper surfaces of the semiconductor elements SCE1, SCE2, and SCE3 of which the upper surfaces of the first semiconductor layers SEM1 are exposed. The first connection electrodes CNE1 may be selectively formed on some of the semiconductor elements SCE1, SCE2, and SCE3 disposed on the common electrode layer CEL through a photo process. The first connection electrodes CNE1 may be formed only on the semiconductor elements SCE1, SCE2, and SCE3 disposed in the display area DPA, and the semiconductor elements SCE1, SCE2, and SCE3 on which the first connection electrodes CNE1 are formed may become the light emitting elements ED. The first connection electrodes CNE1 may be disposed directly on the exposed first semiconductor layers SEM1 of the semiconductor elements SCE1, SCE2, and SCE3 in the display area DPA.

Then, the reflective layers RL1 and RL2 around (or surrounding) portions of outer surfaces of the light emitting elements ED and the semiconductor elements SCE1, SCE2, and SCE3 disposed on the common electrode layer CEL are formed. The reflective layers RL1 and RL2 may be disposed on side surfaces and portions of upper surfaces of the light emitting elements ED and the semiconductor elements SCE1, SCE2, and SCE3 on the insulating layer INS. The first reflective layers RL1 may be disposed on side surfaces of the light emitting elements ED disposed in the display area DPA and portions of upper surfaces of the light emitting elements ED on which the first connection electrodes CNE1 are not disposed, on the insulating layer INS. The second reflective layers RL2 may be disposed on upper surfaces and side surfaces of the semiconductor elements SCE1, SCE2, and SCE3 disposed in the non-display area NDA.

Through the process described above, the semiconductor elements SCE1, SCE2, and SCE3 disposed in the display area DPA among the semiconductor elements SCE1, SCE2, and SCE3 disposed on the common electrode layer CEL may form the light emitting elements ED. Then, a process of classifying the semiconductor elements SCE1, SCE2, and SCE3 disposed in the non-display area NDA into the common electrode elements ND and the dummy elements DE and forming common electrodes is performed.

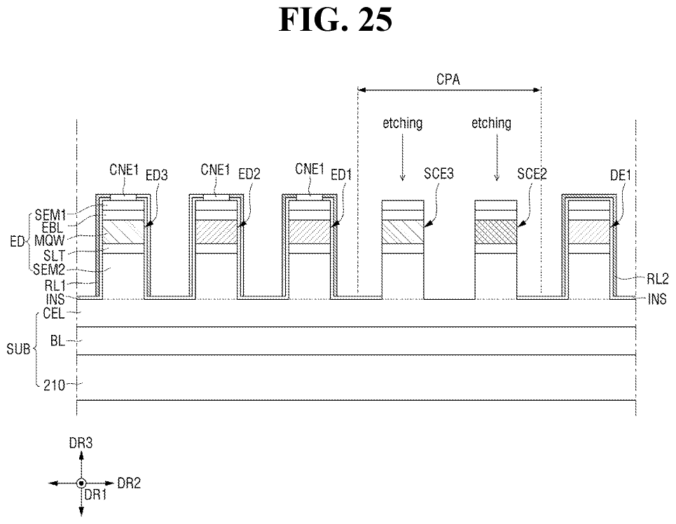

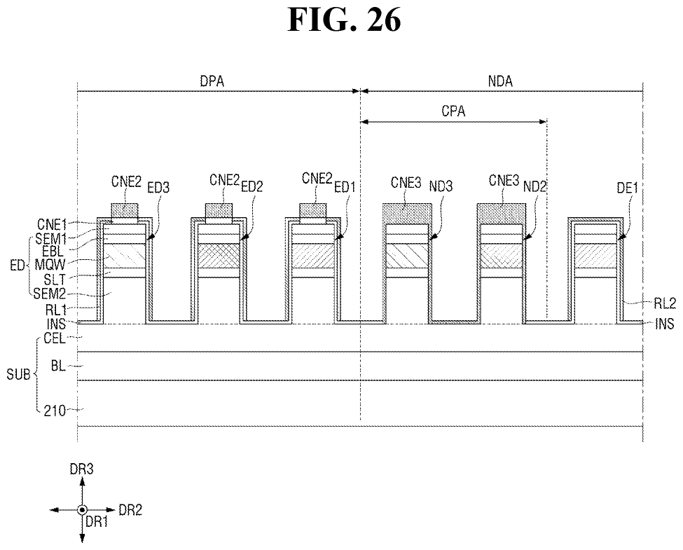

As illustrated in FIGS. 25 and 26, the second connection electrodes CNE2 are formed on the light emitting elements ED, and the third connection electrodes CNE3 are formed on some semiconductor elements SCE1, SCE2, and SCE3 to form the common electrode elements ND and the dummy elements DE. First, a process of removing portions of the insulating layer INS and the second reflective layers RL2 so as to expose outer surfaces of semiconductor elements SCE1, SCE2, and SCE3 disposed in common electrode areas CPA1, CPA2, and CPA3 among the semiconductor elements SCE1, SCE2, and SCE3 disposed in the non-display area NDA is performed. The process may be performed through an etching process using a mask.

The semiconductor elements SCE1, SCE2, and SCE3 of which outer surfaces are not exposed in the etching process described above are the dummy elements DE, and may become any one of first to third dummy elements DE1, DE2, and DE3 according to materials of the active layers MQW1, MQW2, and MQW3. It has been illustrated in FIG. 25 that the first dummy elements DE1 of which outer surfaces are covered by the insulating layer INS and the second reflective layers RL2 are formed. FIG. 25 is a drawing based on the structure of FIG. 8, and thus, the second dummy elements DE2 and the third dummy elements DE3 may be further disposed on the common electrode layer CEL.

Then, the second connection electrodes CNE2 and the third connection electrodes CNE3 are formed, respectively, on the light emitting elements ED1, ED2, and ED3 in the display area DPA, and the semiconductor elements SCE1, SCE2, and SCE3 of which the outer surfaces are exposed in the etching process described above in the common electrode area CPA . The second connection electrodes CNE2 are disposed directly on the first connection electrodes CNE1 on the light emitting elements ED. The third connection electrodes CNE3 may be disposed on the semiconductor elements SCE1, SCE2, and SCE3 disposed in the common electrode areas CPA1, CPA2, and CPA3. In the semiconductor elements SCE1, SCE2, and SCE3 disposed in the common electrode areas CPA1, CPA2, and CPA3, the insulating layer INS and the reflective layer RL2 are removed, such that outer surfaces of the semiconductor layers are exposed, and the third connection electrodes CNE3 may be disposed on outer surfaces and side surfaces of the semiconductor elements SCE1, SCE2, and SCE3 disposed in the common electrode areas CPA1, CPA2, and CPA3. The third connection electrodes CNE3 may be disposed to be in contact with at least the first semiconductor layers SEM1 and the second semiconductor layers SEM2 of the semiconductor elements SCE1, SCE2, and SCE3, and these semiconductor elements SCE1, SCE2, and SCE3 may become the common electrode elements ND of which both ends are short-circuited.

The semiconductor elements SCE1, SCE2, and SCE3 disposed in the common electrode areas CPA1, CPA2, and CPA3 that are short-circuited by the third connection electrodes CNE3 are the common electrode elements ND, and may become any one of first to third common electrode elements ND1, ND2, and ND3 according to materials of the active layers MQW1, MQW2, and MQW3. It has been illustrated in FIG. 26 that the second common electrode elements ND2 and the third common electrode elements ND3 are formed. FIG. 26 is a drawing based on the structure of FIG. 8, and thus, the first common electrode elements ND1 may be further disposed on the common electrode layer CEL.

The display substrate 300 disposed on the second substrate 210 may be fabricated through the processes described above. Then, the display device 10 may be fabricated by bonding the prepared circuit substrate 100 and display substrate 300 to each other.

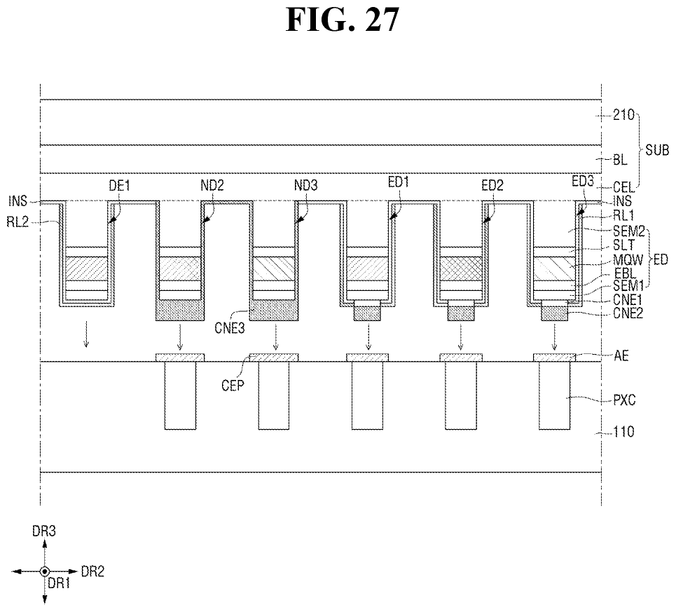

Referring to FIG. 27, the circuit substrate 100 and the display substrate 300 in which the light emitting elements ED, the common electrode elements ND, and the dummy elements DE are formed are bonded to each other (S40). The display substrate 300 formed on the second substrate 210 may be disposed on the display substrate area DSA of the circuit substrate 100. In the process, the second substrate 210 and the display substrate 300 may be aligned with each other on the circuit substrate 100 so that the light emitting elements ED correspond to the pixel electrodes AE of the circuit substrate 100. The second connection electrodes CNE2 disposed in the display area DPA may be aligned to overlap the pixel electrodes AE in the thickness direction, and the third connection electrodes CNE3 disposed in the common electrode areas CPA1, CPA2, and CPA3 may be aligned to overlap the common electrode connection parts CEP in the thickness direction.

When the second substrate 210 and the display substrate 300 are aligned with the circuit substrate 100, a filling layer 500 is disposed between the display substrate 300 and the circuit substrate 100 to bond the display substrate 300 and the circuit substrate 100 to each other. As an example, a material of the filling layer 500 may be injected so that the filling layer 500 fills a space between the display substrate 300 and the circuit substrate 100 when the display substrate 300 and the circuit substrate 100 are aligned with each other, such that the connection electrodes CNE1, CNE2, and CNE3 are in contact with the pixel electrodes AE and the common electrode connection parts CEP. Thereafter, when the injected material of the filling layer 500 is cured, the display substrate 300 and the circuit substrate 100 may be bonded to each other. However, the present disclosure is not limited thereto, and as described above, a process of bonding the circuit substrate 100 and the display substrate 300 to each other may also be performed in a manner of disposing materials of the filling layer 500 on the first substrate 110 and the common electrode layer CEL, respectively, to planarize upper surfaces of the first substrate 110 and the common electrode layer CEL and then attaching the first substrate 110 and the common electrode layer CEL to each other.

The second connection electrodes CNE2 disposed on the light emitting elements ED of the display substrate 300 may be in direct contact with the pixel electrodes AE, and the third connection electrodes CNE3 disposed in the common electrode areas CPA1, CPA2, and CPA3 may be in direct contact with the common electrode connection parts CEP. When the circuit substrate 100 and the display substrate 300 are bonded to each other, both ends of the light emitting elements ED may be electrically connected to the pixel circuit parts PXC of the circuit substrate 100.

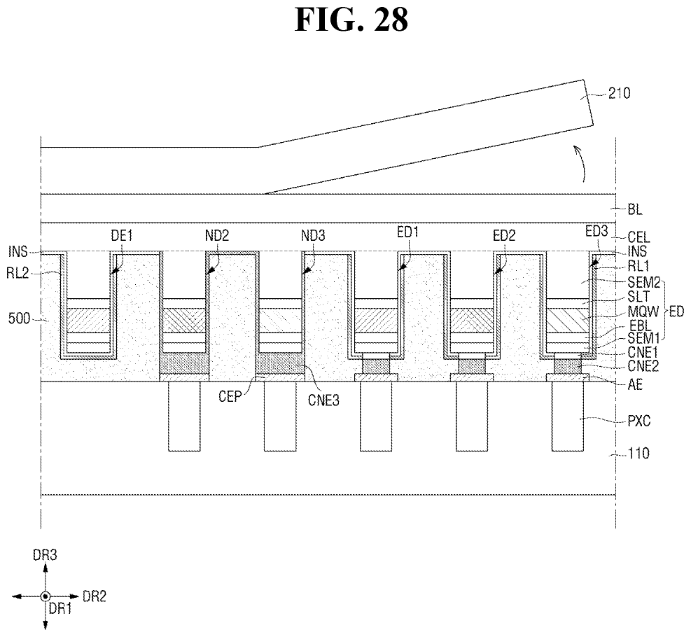

Next, referring to FIG. 28, the display device 10 may be fabricated by removing the second substrate 210 disposed on the base layer BL of the display substrate 300. The method for fabrication of the display device 10 according to one or more embodiments may include a process of entirely forming the semiconductor elements SCE1, SCE2, and SCE3 on the common electrode layer CEL, and then forming the semiconductor elements SCE1, SCE2, and SCE3 as the light emitting elements ED, the common electrode elements ND, and the dummy elements DE. Accordingly, the display device 10 may be formed so that the light emitting elements ED disposed in the display area DPA among the areas of the display substrate 300 have a uniform quality and concentration.

Hereinafter, various embodiments of the display device 10 will be described with further reference to other drawings.

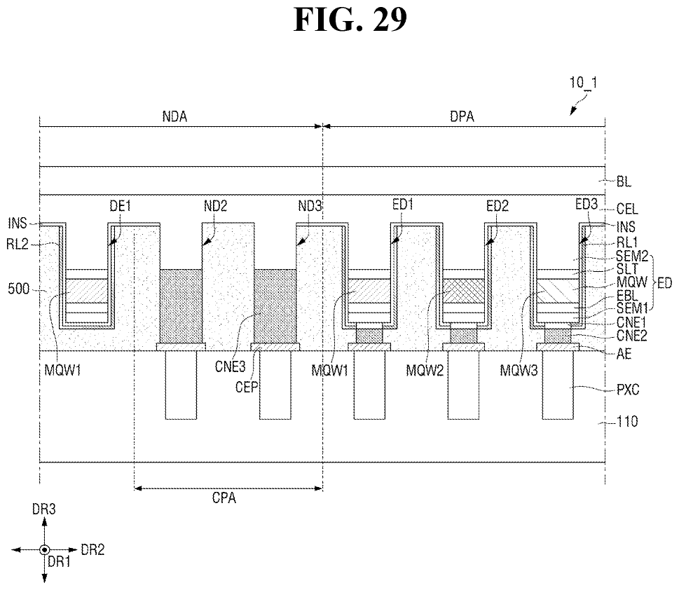

FIG. 29 is a cross-sectional view illustrating a portion of a display device according to one or more embodiments.

Referring to FIG. 29, in a display device 10_1 according to one or more embodiments, the common electrode elements ND disposed under the third connection electrodes CNE3 may include only the second semiconductor layers SEM2. The common electrode elements ND may serve as electrodes electrically connecting the common electrode layer CEL, which is a common electrode of the light emitting elements ED, and the common electrode connection parts CEP to each other together with the third connection electrodes CNE3. The common electrode element ND may serve as one conductive pattern if the first semiconductor layer SEM1 and the second semiconductor layer SEM2 are short-circuited by the third connection electrode CNE3. That is, a structure of the common electrode elements ND may be changed as long as the common electrode elements ND have conductivity between the third connection electrodes CNE3 and the common electrode layer CEL.

The common electrode elements ND may include only the second semiconductor layers SEM2, and the first semiconductor layers SEM1, the superlattice layers SLT, the active layers MQW, and the electron blocking layers EBL may be omitted in the common electrode elements ND. Even though the common electrode elements ND includes only the second semiconductor layers SEM2, materials of the second semiconductor layers SEM2 may be different from each other depending on materials of the active layers MQW of the light emitting elements ED formed in the same process as a process of forming the common electrode elements ND. For example, the first common electrode element ND1 formed in the same process as a process of forming the first light emitting element ED1 including the first active layer MQW1 may include the same material as the second semiconductor layer SEM2 of the first light emitting element ED1, and the second common electrode element ND2 formed in the same process as a process of forming the second light emitting element ED2 including the second active layer MQW2 may include the same material as the second semiconductor layer SEM2 of the second light emitting element ED2. Because the second semiconductor layers SEM2 of the first light emitting element ED1 and the second light emitting element ED2 may include different materials, the first common electrode element ND1 and the second common electrode element ND2 may also include the second semiconductor layers SEM2 made of different materials. Similarly, the third common electrode element ND3 may include the second semiconductor layer SEM2 made of a material different from those of the first common electrode element ND1 and the second common electrode element ND2.

Because the common electrode elements ND includes only the second semiconductor layers SEM2, the third connection electrodes CNE3 may not have a layout for a short-circuit of the common electrode elements ND. For example, the third connection electrode CNE3 may be disposed on one surface of the second semiconductor layer SEM2 and may not be in direct contact with side surfaces of the common electrode layer CEL and the second semiconductor layer SEM2.

As described above, in the display substrate 300, heights of lower surfaces of the connection electrodes CNE1, CNE2, and CNE3 disposed on the light emitting elements ED and the common electrode elements ND from one surface of the common electrode layer CEL may be the same as each other. In one or more embodiments in which the common electrode element ND includes only the second semiconductor layer SEM2, a thickness of the third connection electrode CNE3 may be greater than the sum of thicknesses of the first connection electrode CNE1 and the second connection electrode CNE2. As an example, the thickness of the third connection electrode CNE3 may be the same as the sum of thicknesses of the electron blocking layer EBL, the active layer MQW, the superlattice layer SLT, and the first semiconductor layer SEM1 of the light emitting element ED, the first connection electrode CNE1, and the second connection electrode CNE2. The described embodiment is different from an embodiment of FIG. 8 in structures of the common electrode elements ND and the third connection electrodes CNE3. An etching process of exposing outer surfaces of the semiconductor elements SCE1, SCE2, and SCE3 disposed in the common electrode areas CPA1, CPA2, and CPA3 among processes for fabrication of the display device 10_1 may be performed as a process of etching the electron blocking layers EBL, the active layers MQW, the superlattice layers SLT, and the first semiconductor layers SEM1 of the semiconductor elements SCE1, SCE2, and SCE3.

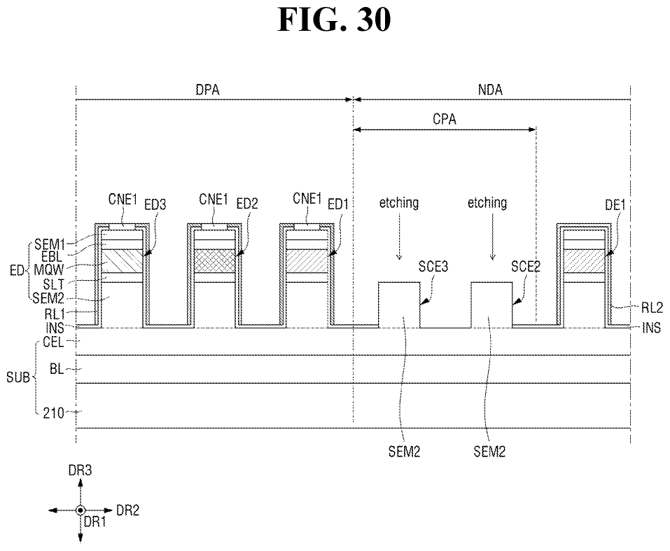

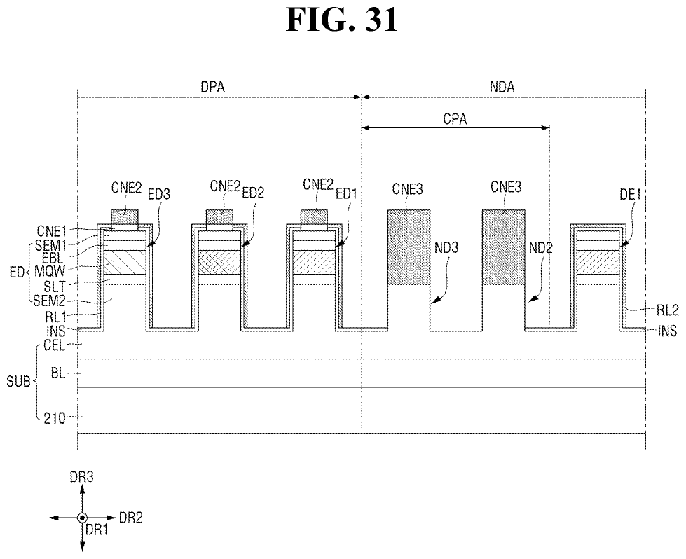

FIGS. 30 and 31 are cross-sectional views illustrating one or more of processes for fabrication of the display device of FIG. 29.

Referring to FIGS. 30 and 31, a process of etching the semiconductor elements SCE1, SCE2, and SCE3 disposed in the common electrode areas CPA1, CPA2, and CPA3 among the processes for fabrication of the display device 10_1 may be performed through an etching process of exposing the outer surface of the semiconductor elements SCE1, SCE2, and SCE3 disposed in the common electrode areas CPA1, CPA2, and CPA3 and etching the electron blocking layers EBL, the active layers MQW, the superlattice layers SLT, and the first semiconductor layers SEM1 of the semiconductor elements SCE1, SCE2, and SCE3. In the etching process, only the second semiconductor layer SEM2 remain in the semiconductor elements SCE1, SCE2, and SCE3 disposed in the common electrode areas CPA1, CPA2, and CPA3, such that the semiconductor elements SCE1, SCE2, and SCE3 may become the common electrode elements ND. The third connection electrode CNE3 may be disposed on one surface of the second semiconductor layer SEM2 of the common electrode element ND. The third connection electrode CNE3 may be disposed to be in contact with at least an upper surface of the second semiconductor layer SEM2, or may be disposed to be in contact with side surfaces of the second semiconductor layer SEM2 and one surface of the common electrode layer CEL as in the above-described embodiment.

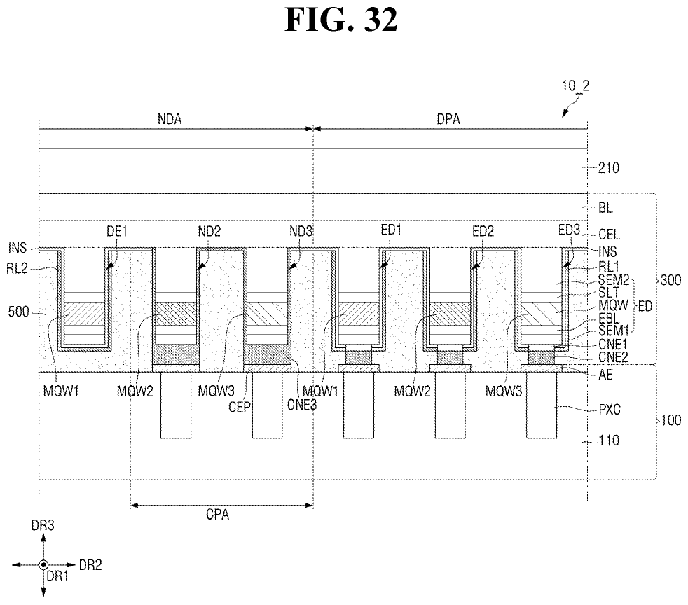

FIG. 32 is a cross-sectional view illustrating a portion of a display device according to one or more embodiments.

Referring to FIG. 32, a display device 10_2 according to one or more embodiments may further include a second substrate 210. The described embodiment is different from the above-described embodiment in that the second substrate 210 on which the display substrate 300 is formed is not removed in processes for fabrication of the display device 10_2. The second substrate 210 is a substrate made of a transparent material, and may be a sapphire substrate or a glass substrate. Accordingly, even though the second substrate 210 is disposed, light emitted from the light emitting elements ED may be emitted through an upper surface of the second substrate 210. Unlike the above-described embodiment, the second substrate 210 is disposed on the base layer BL of the display substrate 300, and thus, durability against external impact may be improved.

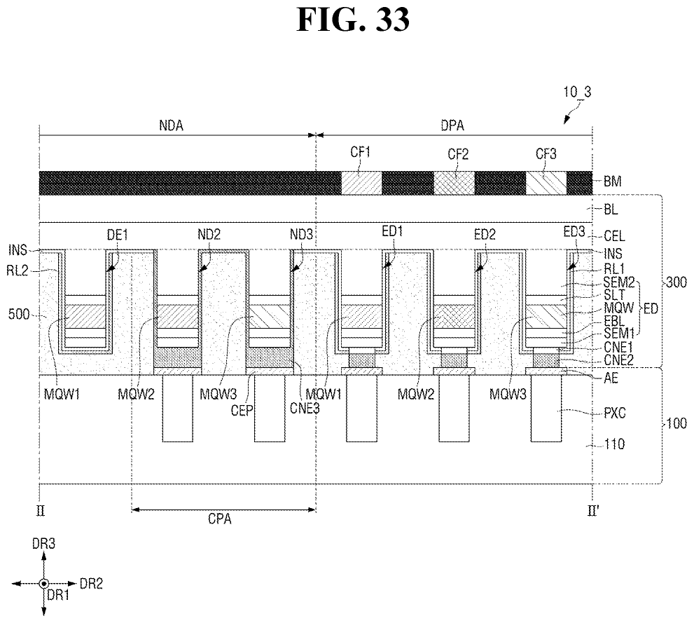

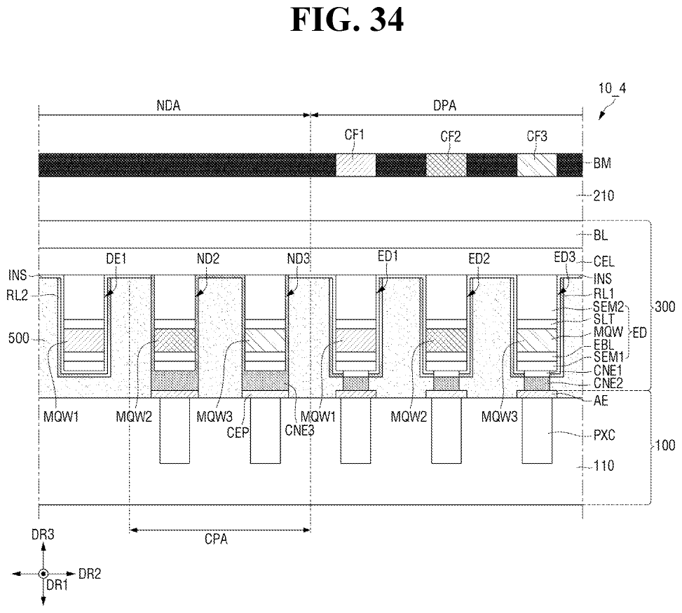

FIGS. 33 and 34 are cross-sectional views illustrating portions of display devices according to one or more embodiments.

Referring to FIGS. 33 and 34, in display devices 10_3 and 10_4 according to one or more embodiments, the display substrate 300 may further include color filters CF1, CF2, and CF3 and light blocking members BM disposed on the base layer BL. In one or more embodiments of FIG. 33, the color filters CF1, CF2, and CF3 and the light blocking members BM may be disposed directly on the base layer BL, and in the embodiment of FIG. 34, the color filters CF1, CF2, and CF3 and light blocking members BM may be disposed on the second substrate 210. embodiments of FIGS. 33 and 34 are different from the above-described embodiment in that the color filters CF1, CF2, and CF3 and the light blocking members BM are further included on the display substrate 300. Hereinafter, a description for overlapping contents will be omitted, and the color filters CF1, CF2, and CF3 and the light blocking members BM will be mainly described.

The light blocking members BM may be disposed on the base layer BL. The third light blocking members BM may be disposed directly on the base layer BL or may be disposed directly on the second substrate 210 in one or more embodiments in which the second substrate 210 is further included. The light blocking members BM may be disposed in an area other than the display area DPA and an area in which the light emitting elements ED are not disposed in the display area DPA and block transmission of light. The light blocking members BM may not overlap the light emitting elements ED in the display area DPA, and may be disposed in a lattice shape.

In one or more embodiments, the light blocking member BM may include an organic light blocking material, and may be formed by a coating process, an exposing process, and the like, of the organic light blocking material. The light blocking member BM may include a dye or a pigment having light blocking properties, and may be a black matrix.

A plurality of color filters CF1, CF2, and CF3 may be disposed on the base layer BL. The color filters CF1, CF2, and CF3 may be disposed directly on the base layer BL or may be disposed directly on the second substrate 210 in one or more embodiments in which the second substrate 210 is further included. The color filters CF1, CF2, and CF3 may be disposed to correspond to areas opened by the light blocking members BM, respectively. Different color filters CF1, CF2, and CF3 may be disposed to be spaced from each other, but are not limited thereto. In some embodiments, the color filters CF1, CF2, and CF3 may also be disposed to overlap each other.

The plurality of color filters CF1, CF2, and CF3 may include a first color filter CF1, a second color filter CF2, and a third color filter CF3. The first color filter CF1 may be disposed to overlap the first light emitting element ED1 in the third direction DR3. The second color filter CF2 may be disposed to overlap the second light emitting element ED2, and the third color filter CF3 may be disposed to overlap the third light emitting element ED3 in the third direction DR3.

The plurality of color filters CF1, CF2, and CF3 may be disposed to fill the areas opened by the light blocking members BM, and portions of the plurality of color filters CF1, CF2, and CF3 may be disposed on the light blocking members BM. However, the present disclosure is not limited thereto, and the color filters CF1, CF2, and CF3 may also be disposed in the areas opened by the light blocking members BM. The respective color filters CF1, CF2, and CF3 may be disposed in an island-shaped pattern, but are not limited thereto. For example, the respective color filters CF1, CF2, and CF3 may form linear patterns extending in one direction in the display area DPA.

In one or more embodiments, the first color filter CF1 may be a red color filter, the second color filter CF2 may be a green color filter, and the third color filter CF3 may be a blue color filter. The respective color filters CF1, CF2, and CF3 may transmit only some of light emitted from the light emitting elements ED, and may block transmission of other light. In the display devices 10_3 and 10-4 according to one or more embodiments, the light emitted from the light emitting elements ED is transmitted through the color filters CF1, CF2, and CF3 and then emitted, and thus, color purity may be further improved.

In one or more embodiments, the different color filters CF1, CF2, and CF3 may also be disposed to overlap each other. The color filters CF1, CF2, and CF3 may partially overlap each other in areas between different light emitting elements ED1, ED2, and ED3 that are spaced from each other. For example, the first color filter CF1 and the second color filter CF2 may be disposed to overlap the first light emitting element ED1 and the second light emitting element ED2, respectively, and may be disposed to overlap each other in an area between the first light emitting element ED1 and the second light emitting element ED2. A portion where the first color filter CF1 and the second color filter CF2 are disposed to overlap each other may block transmission of the red light emitted from the first light emitting element ED1 and the green light emitted from the second light emitting element ED2. In one or more embodiments in which the different color filters CF1, CF2, and CF3 are disposed to overlap each other, the light blocking members BM may be omitted. In the display devices 10_3 and 10_4, the color filters CF1, CF2, and CF3 are disposed to overlap each other, and thus, a process of forming separate light blocking members BM may be omitted.

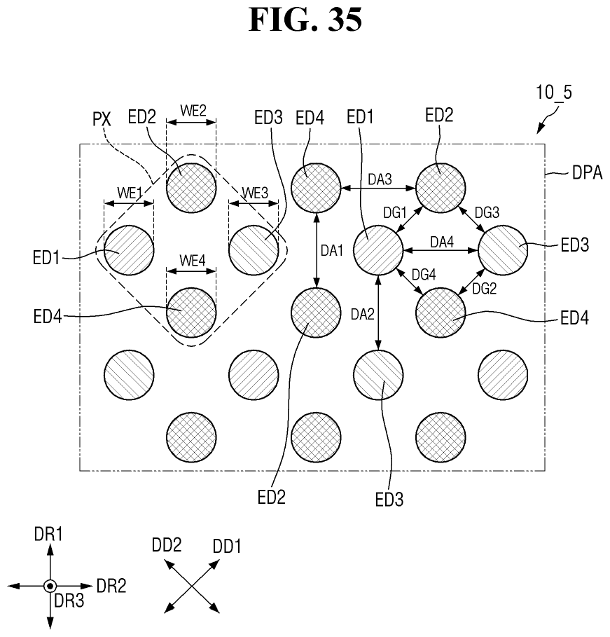

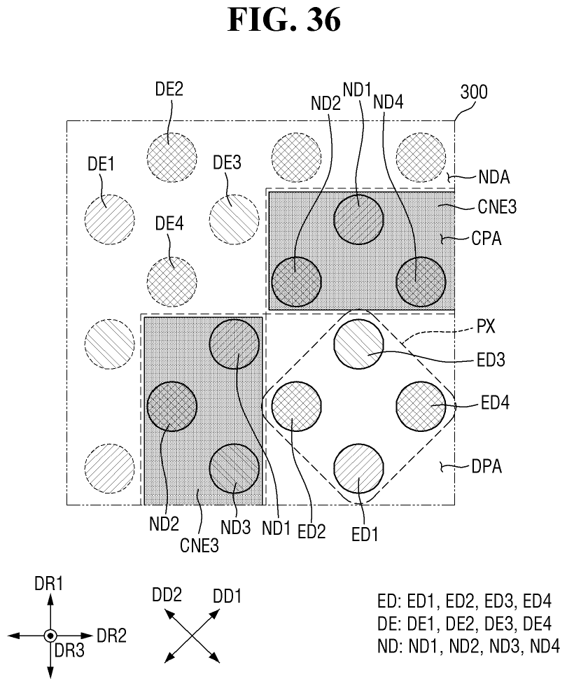

FIG. 35 is a plan view illustrating a relative layout of light emitting elements disposed in a display area of a display device according to one or more embodiments. FIG. 36 is a plan view illustrating a relative layout of light emitting elements and dummy elements disposed on a display substrate in the display device of FIG. 35.

Referring to FIGS. 35 and 36, in a display device 10_5 according to one or more embodiments, each of a plurality of pixels PX may include four light emitting elements ED1, ED2, ED3, and ED4, a plurality of light emitting elements ED, common electrode elements ND, and dummy elements DE may be arranged to be spaced from each other in the first direction DR1 and the second direction DR2, and elements spaced from each other so as to be most adjacent to each other may be spaced from each other in diagonal directions DD1 and DD2 between the first direction DR1 and the second direction DR2. The described embodiment is different from the embodiment of FIG. 5 in the number of light emitting elements ED constituting one pixel PX and an arrangement of the light emitting elements ED. Hereinafter, a description for overlapping contents will be omitted and contents different from those described above will be mainly described.

Each of the pixels PX may include a first light emitting element ED1 emitting light of a first color, a second light emitting element ED2 emitting light of a second color, a third light emitting element ED3 emitting light of a third color, and a fourth light emitting element ED4 emitting the light of the second color. In the display area DPA, the first light emitting elements ED1 and the third light emitting elements ED3 may be alternately disposed along the first direction DR1 and the second direction DR2. The second light emitting elements ED2 and the fourth light emitting elements ED4 may also be alternately disposed along the first direction DR1 and the second direction DR2. The first light emitting elements ED1, the second light emitting elements ED2, the third light emitting elements ED3, and the fourth light emitting elements ED4 may be alternately disposed in the diagonal directions DD1 and DD2 between the first direction DR1 and the second direction DR2. The diagonal directions DD1 and DD2 may be oblique directions inclined from the first direction DR1 and the second direction DR2.

For example, in each of the plurality of pixels PX, the first light emitting elements ED1 and the second light emitting elements ED2 may be alternately disposed along a first diagonal direction DD1 between one side in the first direction DR1 and one side in the second direction DR2, and the third light emitting elements ED3 and the fourth light emitting elements ED4 may be alternately disposed along the first diagonal direction DD1. In each of the plurality of pixels PX, the first light emitting elements ED1 and the fourth light emitting elements ED4 may be alternately disposed in a second diagonal direction DD2 between one side in the first direction DR1 and the other side in the second direction DR2, and the second light emitting elements ED2 and the third light emitting elements ED3 may be alternately disposed in the second diagonal direction DD2. The first diagonal direction DD1 and the second diagonal direction DD2 may cross each other.

The fourth light emitting element ED4 may be substantially the same as the second light emitting element ED2. The fourth light emitting element ED4 may include the second active layer MQW2 to emit green light, which is the light of the second color, and may have the same structure as the second light emitting element ED2.

In one or more embodiments, the first light emitting element ED1, the second light emitting element ED2, the third light emitting element ED3, and the fourth light emitting element ED4 may have the same diameter. For example, a first diameter WE1 of the first light emitting element ED1, a second diameter WE2 of the second light emitting element ED2, a third diameter WE3 of the third light emitting element ED3, and a fourth diameter WE4 of the fourth light emitting element ED4 may be the same as each other. Even in a case of the embodiment of FIG. 5, diameters of the first to third light emitting elements ED1, ED2, and ED3 may be the same as each other. However, the present disclosure is not limited thereto. In one or more embodiments, diameters of the light emitting elements ED1, ED2, ED3, and ED4 may also be different from each other.

Intervals DA1 and DA3 between the second light emitting element ED2 and the fourth light emitting element ED4 adjacent to each other may be the same as intervals DA2 and DA4 between the first light emitting element ED1 and the third light emitting element ED3 adjacent to each other. For example, a first interval DA1 between the second light emitting element ED2 and the fourth light emitting element ED4 adjacent to each other in the first direction DR1 may be the same as a second interval DA2 between the first light emitting element ED1 and the third light emitting element ED3 adjacent to each other in the first direction DR1. A third interval DA3 between the second light emitting element ED2 and the fourth light emitting element ED4 adjacent to each other in the second direction DR2 may be the same as a fourth interval DA4 between the first light emitting element ED1 and the third light emitting element ED3 adjacent to each other in the second direction DR2. In addition, a first diagonal interval DG1 between the first light emitting element ED1 and the second light emitting element ED2 adjacent to each other in the first diagonal direction DD1 may be the same as a second diagonal interval DG2 between the third light emitting element ED3 and the fourth light emitting element ED4 adjacent to each other in the first diagonal direction DD1. A third diagonal interval DG3 between the second light emitting element ED2 and the third light emitting element ED3 adjacent to each other in the second diagonal direction DD2 may be the same as a fourth diagonal interval DG4 between the first light emitting element ED1 and the fourth light emitting element ED4 adjacent to each other in the second diagonal direction DD2. However, the present disclosure is not limited thereto. The intervals between the light emitting elements ED adjacent to each other may be changed depending on a layout, diameters, and the like, of the light emitting elements ED.

It has been illustrated in FIG. 35 that the first light emitting element ED1 emits red light, which is the light of the first color, the second light emitting element ED2 and the fourth light emitting element ED4 emit green light, which is the light of the second color, and the third light emitting element ED3 emits blue light, which is the light of the third color, but the present disclosure is not limited thereto. In one or more embodiments, the first light emitting element ED1 may emit red light, which is the light of the first color, the second light emitting element ED2 and the fourth light emitting element ED4 may emit blue light, which is the light of the third color, and the third light emitting element ED3 may emit green light, which is the light of the second color. Alternatively, the first light emitting element ED1 may emit green light, which is the light of the second color, the second light emitting element ED2 and the fourth light emitting element ED4 may emit red light, which is the light of the first color, and the third light emitting element ED3 may emit blue light, which is the light of the third color. Alternatively, the fourth light emitting element ED4 may emit yellow light, which is light of a fourth color different from the first to third colors. The yellow light, which is the light of the fourth color, may have a central wavelength band in the range of 550 nm to 600 nm, but is not limited thereto.

The common electrode elements ND may include first common electrode elements ND1, second common electrode elements ND2, third common electrode elements ND3, and fourth common electrode elements ND4 including active layers MQW made of different materials. The dummy elements DE may include first dummy elements DE1, second dummy elements DE2, third dummy elements DE3, and fourth dummy elements DE4 including active layers MQW made of different materials. Layouts, arrangements, and the like, of the plurality of common electrode elements ND and dummy elements DE may be substantially the same as a layout, an arrangement, and the like, of the light emitting elements ED. Different common electrode elements ND and different dummy elements DE may be spaced from each other in any one of the first direction DR1, the second direction DR2, the first diagonal direction DD1, and the second diagonal direction DD2, respectively.

It has been illustrated in FIGS. 35 and 36 that each of the first to fourth light emitting elements ED1, ED2, ED3, and ED4 has a circular shape in a plan view, but the present disclosure is not limited thereto. As described above, each of the light emitting elements ED may have a polygonal shape such as a triangular shape, a quadrangular shape, a pentagonal shape, a hexagonal shape, and an octagonal shape, an elliptical shape, or an irregular shape.

In FIGS. 35 and 36, the intervals DA1 to DA4 and DG1 to DG4 between the first to fourth light emitting elements ED1, ED2, ED3 and ED4 have been illustrated as the shortest intervals based on outer side portions of the respective light emitting elements ED1, ED2, ED3, and ED4. However, the present disclosure is not limited thereto. The intervals DA1 to DA4 and DG1 to DG4 between the light emitting elements ED1, ED2, ED3 and ED4 may also be illustrated on the basis of the centers of the light emitting elements ED1, ED2, ED3 and ED4.

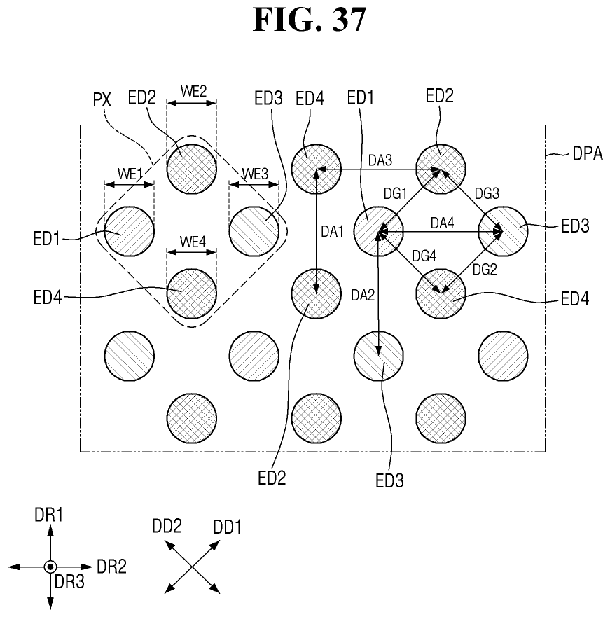

FIG. 37 is a plan view illustrating a relative layout of light emitting elements disposed in a display area of the display device according to one or more embodiments.

Referring to FIG. 37 in addition to FIGS. 35 and 36, intervals DA1 and DA3 between centers of the second light emitting element ED2 and the fourth light emitting element ED4 adjacent to each other may be the same as intervals DA2 and DA4 between centers of the first light emitting element ED1 and the third light emitting element ED3 adjacent to each other. For example, a first interval DA1 between centers of the second light emitting element ED2 and the fourth light emitting element ED4 adjacent to each other in the first direction DR1 may be the same as a second interval DA2 between centers of the first light emitting element ED1 and the third light emitting element ED3 adjacent to each other in the first direction DR1. A third interval DA3 between centers of the second light emitting element ED2 and the fourth light emitting element ED4 adjacent to each other in the second direction DR2 may be the same as a fourth interval DA4 between centers of the first light emitting element ED1 and the third light emitting element ED3 adjacent to each other in the second direction DR2. In addition, a first diagonal interval DG1 between centers of the first light emitting element ED1 and the second light emitting element ED2 adjacent to each other in the first diagonal direction DD1 may be the same as a second diagonal interval DG2 between centers of the third light emitting element ED3 and the fourth light emitting element ED4 adjacent to each other in the first diagonal direction DD1. A third diagonal interval DG3 between centers of the second light emitting element ED2 and the third light emitting element ED3 adjacent to each other in the second diagonal direction DD2 may be the same as a fourth diagonal interval DG4 between centers of the first light emitting element ED1 and the fourth light emitting element ED4 adjacent to each other in the second diagonal direction DD2.

A case where the intervals DA1 to DA4 and DG1 to DG4 between the centers of the light emitting elements ED1, ED2, ED3, and ED4 are the same as each other has been illustrated in the described embodiment, but the present disclosure is not limited thereto. The intervals between the centers of the light emitting elements ED1, ED2, ED3, and ED4 may also be modified similarly to those described above with reference to an embodiment of FIGS. 35 and 36.

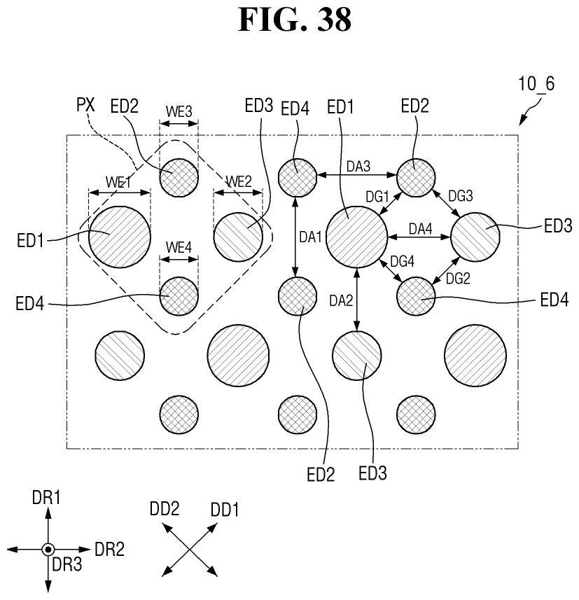

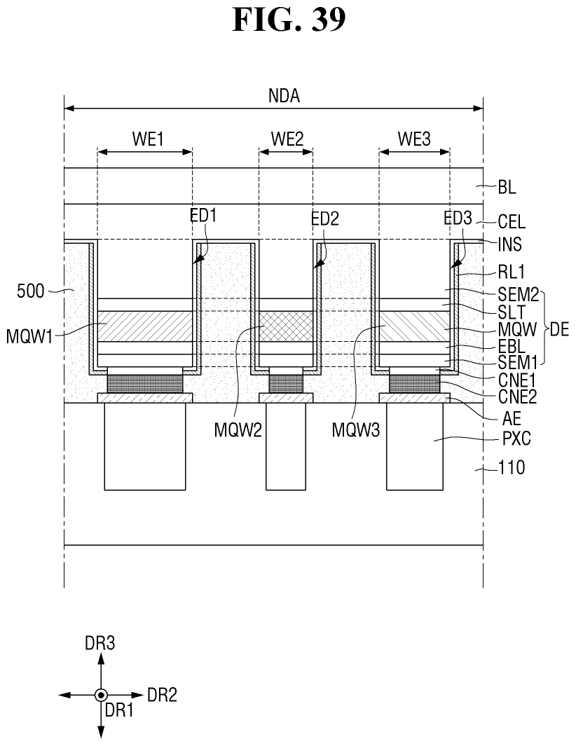

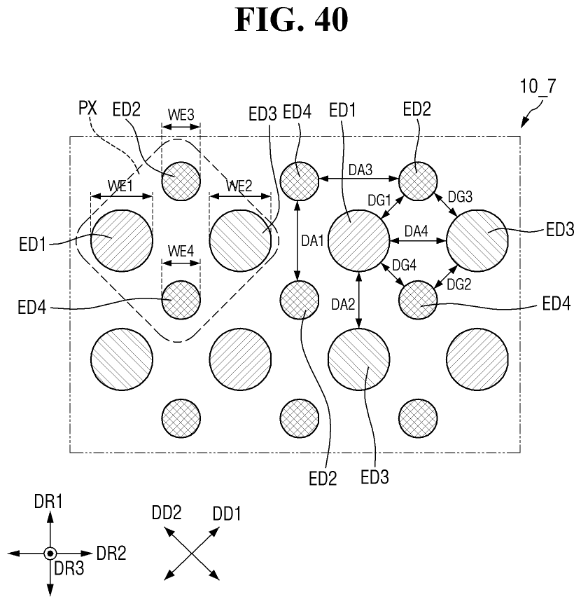

FIG. 38 is a plan view illustrating a relative layout of light emitting elements disposed in a display area of a display device according to one or more embodiments. FIG. 39 is a cross-sectional view illustrating a portion of the display device of FIG. 38. FIG. 40 is a plan view illustrating a relative layout of light emitting elements disposed in a display area of a display device according to one or more embodiments.

Referring to FIGS. 38 to 40, in display devices 10_6 and 10_7 according to one or more embodiments, sizes of light emitting elements ED1, ED2, ED3, and ED4 may be different from each other. In the display device 10_6 of FIGS. 38 and 39, a first diameter WE1 of a first light emitting element ED1 may be greater than each of diameters WE2, WE3, and WE4 of a second light emitting element ED2, a third light emitting element ED3, and a fourth light emitting element ED4, and a third diameter WE3 of the third light emitting element ED3 may be greater than the diameters WE2 and WE4 of the second light emitting element ED2 and the fourth light emitting element ED4. A second diameter WE2 of the second light emitting element ED2 may be the same as a fourth diameter WE4 of the fourth light emitting element ED4. An embodiment of FIG. 40 is different from an embodiment of FIGS. 38 and 39 in that the first diameter WE1 of the first light emitting element ED1 is the same as the third diameter WE3 of the third light emitting element ED3.

In processes for fabrication of the display devices 10_6 and 10_7, the respective light emitting elements ED, common electrode elements ND, and dummy elements DE may have diameters corresponding to sizes of the holes H1, H2, and H3 formed in the support layer SPL. In the processes for fabrication of the display devices 10_6 and 10_7, diameters of the respective light emitting elements ED, common electrode elements ND, and the dummy elements DE disposed in the display substrate 300 may be adjusted by adjusting the diameters of the holes H1, H2, and H3 formed in the support layer SPL so as to be different from each other.

Accordingly, intervals between the light emitting elements ED adjacent to each other may be partially different from each other.

For example, a first interval DA1 between the second light emitting element ED2 and the fourth light emitting element ED4 adjacent to each other in the first direction DR1 may be greater than a second interval DA2 between the first light emitting element ED1 and the third light emitting element ED3 adjacent to each other in the first direction DR1. A third interval DA3 between the second light emitting element ED2 and the fourth light emitting element ED4 adjacent to each other in the second direction DR2 may be greater than a fourth interval DA4 between the first light emitting element ED1 and the third light emitting element ED3 adjacent to each other in the second direction DR2. In addition, a first diagonal interval DG1 between the first light emitting element ED1 and the second light emitting element ED2 adjacent to each other in the first diagonal direction DD1 may be different from a second diagonal interval DG2 between the third light emitting element ED3 and the fourth light emitting element ED4 adjacent to each other in the first diagonal direction DD1. A third diagonal interval DG3 between the second light emitting element ED2 and the third light emitting element ED3 adjacent to each other in the second diagonal direction DD2 may be different from a fourth diagonal interval DG4 between the first light emitting element ED1 and the fourth light emitting element ED4 adjacent to each other in the second diagonal direction DD2.

In one or more embodiments in which the first diameter WE1 of the first light emitting element ED1 is greater than the third diameter WE3 of the third light emitting element ED3, the first diagonal interval DG1 may be smaller than the second diagonal interval DG2, and the third diagonal interval DG3 may be greater than the fourth diagonal interval DG4. However, the present disclosure is not limited thereto. The intervals between the light emitting elements ED adjacent to each other may be changed depending on a layout, diameters, and the like, of the light emitting elements ED. For example, in one or more embodiments in which the first diameter WE1 of the first light emitting element ED1 is the same as the third diameter WE3 of the third light emitting element ED3, the first diagonal interval DG1 may be the same as the second diagonal interval DG2, and the third diagonal interval DG3 may be the same as the fourth diagonal interval DG4.

It has been illustrated in FIGS. 38 to 40 that the first light emitting element ED1 and the third light emitting element ED3 emit red light, which is light of a first color, and blue light, which is light of a third color, respectively, and the second light emitting element ED2 and the fourth light emitting element ED4 emit green light, which is light of a second color, but the present disclosure is not limited thereto. Similar to the above-described embodiments, diameters of the light emitting elements ED1, ED2, ED3, and ED4, intervals between the light emitting elements ED1, ED2, ED3, and ED4, colors of light emitted from the respective light emitting elements ED may be variously changed.

In FIGS. 38 to 40, intervals based on outer side portions of the light emitting elements ED1, ED2, ED3, and ED4 have been illustrated and described as the intervals DA1 to DA4 and DG1 to DG4 between the first to fourth light emitting elements ED1, ED2, ED3 and ED4, but the present disclosure is not limited thereto. Similar to the embodiment of FIG. 37, the intervals between the light emitting elements ED1, ED2, ED3, and ED4 described in FIGS. 38 to 40 may be similarly applied even though the intervals between the light emitting elements ED1, ED2, ED3, and ED4 are compared with each other on the basis of centers of the light emitting elements ED1, ED2, ED3, and ED4. However, in one or more embodiments in which the diameters of the respective light emitting elements ED1, ED2, ED3, and ED4 are different from each other, size relationships between the intervals between the light emitting elements ED1, ED2, ED3, and ED4 based on the outer side portions of the light emitting elements ED1, ED2, ED3, and ED4 and the intervals between the light emitting elements ED1, ED2, ED3, and ED4 based on the centers of the light emitting elements ED1, ED2, ED3, and ED4 may be different from each other.

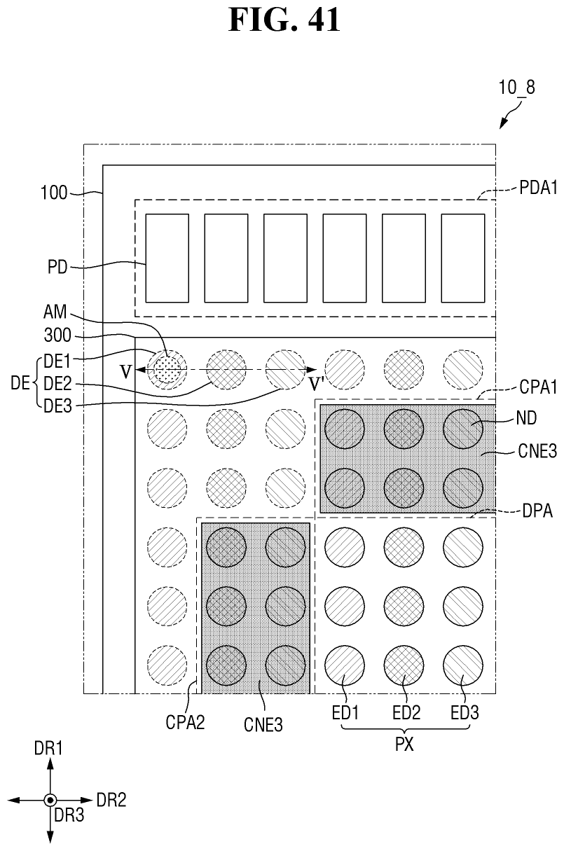

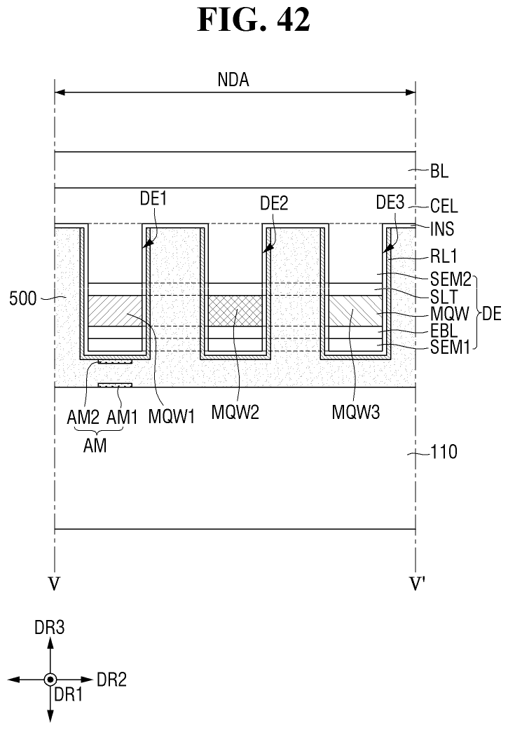

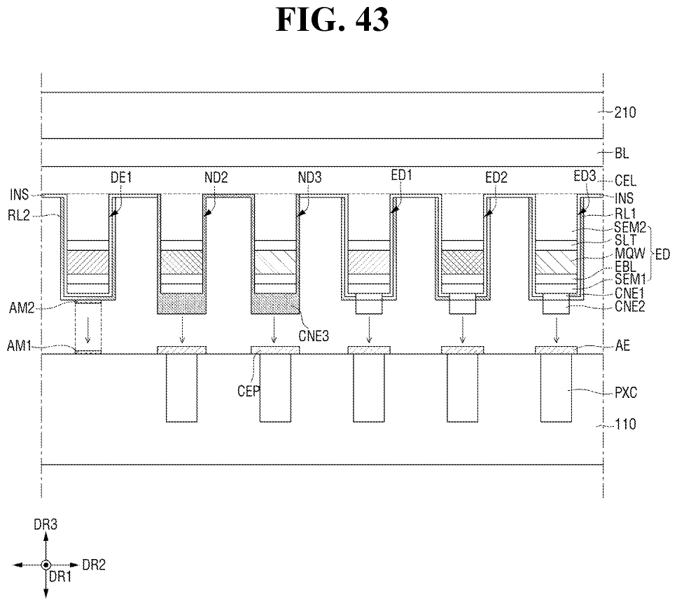

FIG. 41 is a plan view illustrating a portion of a display substrate and a circuit substrate of a display device according to another embodiment. FIG. 42 is a cross-sectional view taken along line V-V′ of FIG. 41. FIG. 43 is a cross-sectional view illustrating one of processes for fabrication of the display device of FIG. 41.

Referring to FIGS. 41 to 43, a display device 10_8 according to one or more embodiments may further include alignment patterns AM: AM1 and AM2. The display device 10_8 may include a first alignment pattern AM1 disposed in the non-display area NDA in the display substrate area DSA of the circuit substrate 100 and a second alignment pattern AM2 disposed on the dummy elements DE disposed in the non-display area NDA of the display substrate 300.

In processes for fabrication of the display device 10_8, the display substrate 300 and the second substrate 210 may be bonded to each other in a state in which they are aligned with the circuit substrate 100. Here, the light emitting elements ED of the display substrate 300 may be aligned to correspond to the pixel electrodes AE of the circuit substrate 100, respectively, and the light emitting elements ED and the pixel electrodes AE may be aligned with each other through the alignment patterns AM1 and AM2. The circuit substrate 100 may include the first alignment pattern AM1 disposed in the non-display area NDA of the first substrate 110, and the display substrate 300 may include the second alignment pattern AM2 disposed to overlap at least one of the dummy elements DE in the third direction DR3. The second alignment pattern AM2 may be disposed directly on the second reflective layer RL2 covering the dummy element DE.

In the processes for fabrication of the display device 10_8, the circuit substrate 100 and the display substrate 300 may be aligned with each other so that the first alignment pattern AM1 and the second alignment pattern AM2 overlap each other. When the circuit substrate 100 and the display substrate 300 are bonded to each other in such a state, the first alignment pattern AM1 and the second alignment pattern AM2 in the display device 10_8 may overlap each other in the thickness direction or the third direction DR3. It has been illustrated in FIGS. 41 to 43 that the first alignment pattern AM1 and the second alignment pattern AM2 overlap each other in a state in which they are spaced from each other, but the present disclosure is not limited thereto. The first alignment pattern AM1 and the second alignment pattern AM2 may be in direct contact with each other. In addition, it has been illustrated in FIGS. 41 to 43 that one first alignment pattern AM1 and one second alignment pattern AM2 are disposed in the circuit substrate 100 and the display substrate 300, respectively, but the present disclosure is not limited thereto.

Positions of and an alignment between the first alignment pattern AM1 and the second alignment pattern AM2 may correspond to an alignment between the plurality of light emitting elements ED and the pixel electrodes AE and an alignment between the third connection electrodes CNE3 and the electrode connection parts CEP. The alignment patterns AM1 and AM2 of the circuit substrate 100 and the display substrate 300 may be disposed at positions where the plurality of light emitting elements ED and the pixel electrodes AE may be aligned with each other when the alignment patterns AM1 and AM2 are aligned with each other. The display device 10_8 may further include the alignment patterns AM1 and AM2 to precisely align the circuit substrate 100 and the display substrate 300 with each other and to prevent an alignment defect, a contact defect, and the like, between the second connection electrodes CNE2 and the pixel electrodes AE.

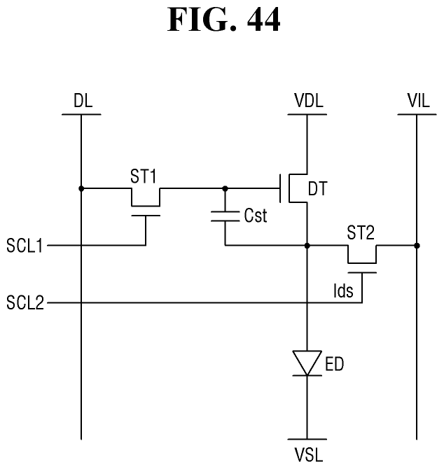

FIG. 44 is an equivalent circuit diagram of one pixel of a display device according to one or more embodiments. In FIG. 44, an example of a pixel circuit diagram included in one pixel PX of FIG. 5 is illustrated.

Referring to FIG. 44, the light emitting element ED emits light according to a driving current. An amount of light emitted from the light emitting element ED may be proportional to the driving current Ids. The light emitting element ED may be an inorganic light emitting element including an anode electrode, a cathode electrode, and an inorganic semiconductor disposed between the anode electrode and the cathode electrode.

The anode electrode of the light emitting element ED may be connected to a source electrode of a driving transistor DT, and the cathode electrode of the light emitting element ED may be connected to a second power line VSL to which a low potential voltage lower than a high potential voltage is supplied.

The driving transistor DT adjusts a current flowing from a first power line VDL to which a first source voltage is supplied to the light emitting element ED according to a voltage difference between a gate electrode and the source electrode of the driving transistor DT. The gate electrode of the driving transistor DT may be connected to a first electrode of a first transistor ST1, the source electrode of the driving transistor DT may be connected to the anode electrode of the light emitting element ED, and a drain electrode of the driving transistor DT may be connected to the first power line VDL to which the high potential voltage is applied.

The first transistor ST1 is turned on by a first scan signal (e.g., a high-level signal) of a first scan line SCL1 to connect a data line DL to the gate electrode of the driving transistor DT. A gate electrode of the first transistor ST1 may be connected to the first scan line SCL1, the first electrode of the first transistor ST1 may be connected to the gate electrode of the driving transistor DT, and a second electrode of the first transistor ST1 may be connected to the data line DL.

A second transistor ST2 is turned on by a second scan signal (e.g., a high-level signal) of a second scan line SCL2 to connect an initialization voltage line VIL to the source electrode of the driving transistor DT. A gate electrode of the second transistor ST2 may be connected to the second scan line SCL2, a first electrode of the second transistor ST2 may be connected to the initialization voltage line VIL, and a second electrode of the second transistor ST2 may be connected to the source electrode of the driving transistor DT.

The first electrode of each of the first and second transistors ST1 and ST2 may be a source electrode, and the second electrode of each of the first and second transistors ST1 and ST2 may be a drain electrode, but the present disclosure is not limited thereto. That is, the first electrode of each of the first and second transistors ST1 and ST2 may be a drain electrode, and the second electrode of each of the first and second transistors ST1 and ST2 may be a source electrode.

A capacitor Cst is formed between the gate electrode and the source electrode of the driving transistor DT. The capacitor Cst stores a difference voltage (or change) between a gate voltage and a source voltage of the driving transistor DT.

It has been mainly described in FIG. 44 that the driving transistor DT and the first and second transistors ST1 and ST2 are formed as N-type metal oxide semiconductor field effect transistors (MOSFETs), but it is to be noted that the present disclosure is not limited thereto. The driving transistor DT and the first and second transistors ST1 and ST2 may also be formed as P-type MOSFETs.

In one or more embodiments, a display device for displaying an image may be applied to various devices and apparatuses.

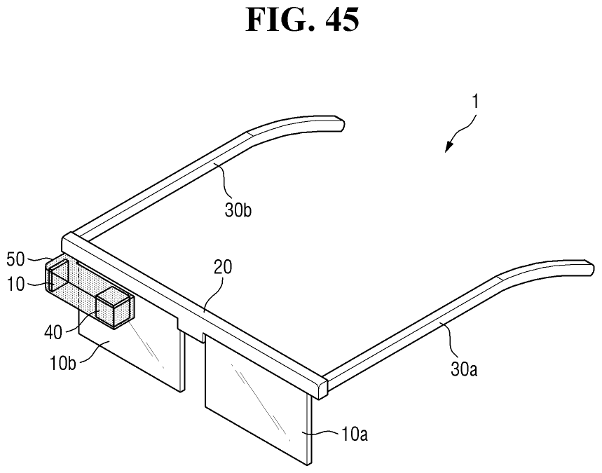

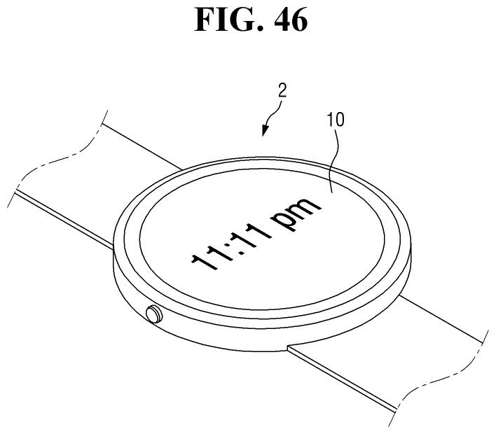

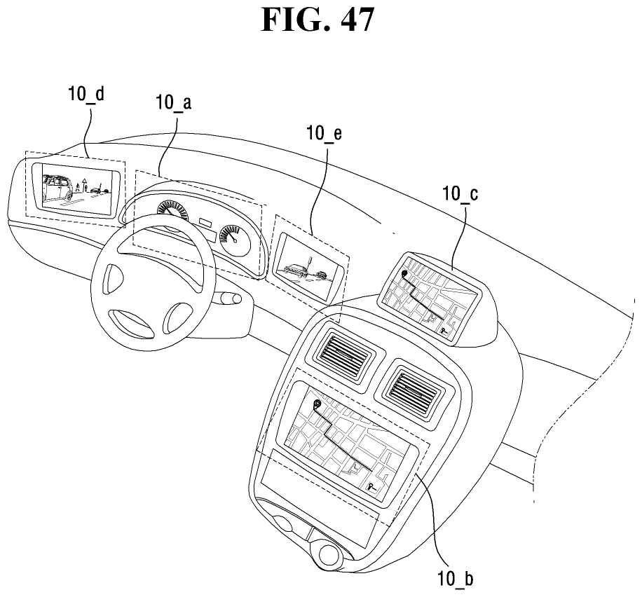

FIG. 45 illustrates a virtual reality device 1 to which the display device 10 according to one or more embodiments is applied, and FIG. 46 illustrates a smart watch 2 to which the display device 10 according to one or more embodiments is applied. FIG. 47 illustrates that display devices 10_a, 10_b, 10_c, 10_d, and 10_e according to one or more embodiments are applied to a display unit of a vehicle.

Referring to FIG. 45, the virtual reality device 1 according to one or more embodiments may be a glasses-type device. The virtual reality device 1 according to one or more embodiments may include the display device 10, a left eye lens 10a, a right eye lens 10b, a support frame 20, eyeglass frame legs 30a and 30b, a reflective member 40, and a display device accommodating part 50.

The virtual reality device 1 including the eyeglass frame legs 30a and 30b has been illustrated in FIG. 45, but the virtual reality device 1 according to one or more embodiments may also be applied to a head mounted display including a head mounted band that may be mounted on a user's head instead of the eyeglass frame legs 30a and 30b. The virtual reality device 1 according to one or more embodiments is not limited to a structure illustrated in FIG. 45, and may be applied in various forms to various other electronic devices.

The display device accommodating part 50 may include the display device 10 and the reflective member 40. An image displayed on the display device 10 may be reflected by the reflective member 40 and provided to a user's right eye through the right eye lens 10b. Accordingly, a user may view a virtual reality image displayed on the display device 10 through his/her right eye.

The display device accommodating part 50 may be disposed at a right distal end of the support frame 20, but is not limited thereto. For example, the display device accommodating part 50 may be disposed at a left distal end of the support frame 20, and an image displayed on the display device 10 may be reflected by the reflective member 40 and provided to a user's left eye through the left eye lens 10a. Accordingly, the user may view a virtual reality image displayed on the display device 10 through his/her left eye. Alternatively, the display device accommodating parts 50 may be disposed at both the left and right distal ends of the support frame 20. In this case, the user may view a virtual reality image displayed on the display device 10 through both his/her left and right eyes.

Referring to FIG. 46, the display device 10 according to one or more embodiments may be applied to a smart watch 2, which is one of the smart devices.

Referring to FIG. 47, display devices 10_a, 10_b, and 10_c according to one or more embodiments may be applied to an instrument board of the vehicle, applied to a center fascia of the vehicle, or applied to a center information display (CID) disposed on a dashboard of the vehicle. In addition, display devices 10_d and 10_e according to one or more embodiments may be applied to room mirror displays substituting for side mirrors of the vehicle.

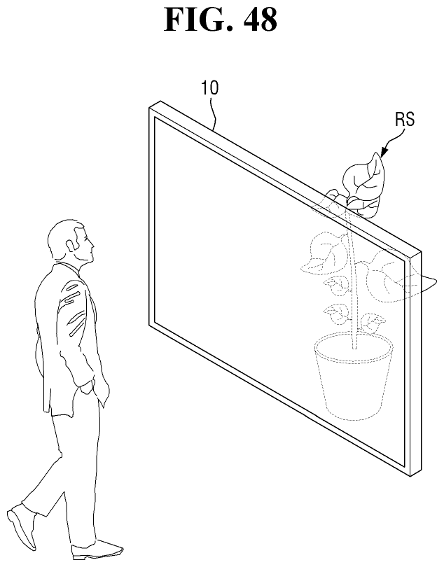

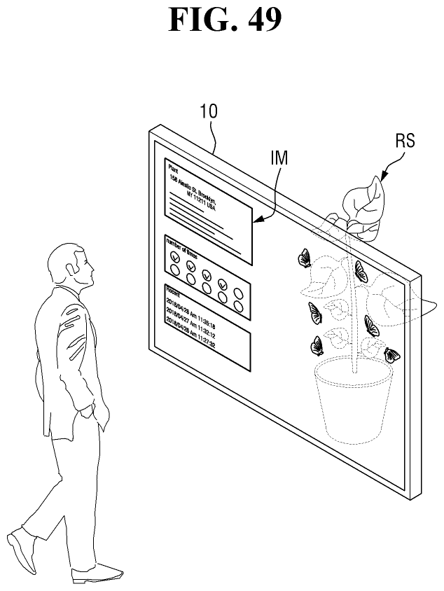

FIGS. 48 and 49 are views illustrating a transparent display device including a display device according to one or more embodiments.

Referring to FIGS. 48 and 49, the display device 10 according to one or more embodiments may be applied to a transparent display device. The transparent display device may transmit light while displaying an image IM. A user positioned on a front surface of the transparent display device may not only view the image IM displayed on the display device 10, but also see an object RS or a background positioned on a rear surface of the transparent display device.

In concluding the detailed description, those skilled in the art will appreciate that many variations and modifications can be made to one or more embodiments without substantially departing from the scope and principles of the present disclosure. Therefore, the embodiments of the present are used in a generic and descriptive sense only and not for purposes of limitation.

What is claimed is:

1. A display device comprising:
a plurality of pixel electrodes and common electrode connection parts that are spaced from each other on a first substrate;
a plurality of light emitting elements on the plurality of pixel electrodes;
a plurality of common electrode elements on the common electrode connection parts; and
a common electrode layer on the plurality of light emitting elements and the plurality of common electrode elements,
wherein each of the plurality of light emitting elements comprises a first semiconductor layer, a second semiconductor layer, and an active layer between the first semiconductor layer and the second semiconductor layer,
wherein each of the plurality of common electrode elements comprises at least the second semiconductor layer, and
wherein the common electrode layer comprises a same material as the second semiconductor layer to be connected to the second semiconductor layers of the plurality of light emitting elements and the second semiconductor layers of the plurality of common electrode elements.

2. The display device of claim 1, wherein each of the plurality of common electrode elements comprises the active layer on one surface of the second semiconductor layer, and the first semiconductor layer on the active layer,
wherein the plurality of light emitting elements comprises first light emitting elements comprising a first active layer to emit light of a first color and second light emitting elements comprising a second active layer different from the first active layer and to emit light of a second color, and
wherein the plurality of common electrode elements comprises first common electrode elements comprising the first active layer and second common electrode elements comprising the second active layer.

3. The display device of claim 2, further comprising first connection electrodes on one surfaces of the first semiconductor layers of the plurality of light emitting elements, second connection electrodes between the first connection electrodes and the pixel electrodes, and third connection electrodes on the plurality of common electrode elements,
wherein the second connection electrodes are in direct contact with the plurality of pixel electrodes, respectively, and the third connection electrodes are in direct contact with the common electrode connection parts, respectively.

4. The display device of claim 3, wherein a third connection electrode of the third connection electrodes is on side surfaces of a common electrode element of the plurality of common electrode elements to be in direct contact with each of the first semiconductor layer and the second semiconductor layer.

5. The display device of claim 2, wherein the plurality of light emitting elements further comprises third light emitting elements comprising a third active layer different from the first active layer and the second active layer and to emit light of a third color, and
wherein the plurality of common electrode elements further comprises third common electrode elements comprising the third active layer.

6. The display device of claim 1, further comprising connection electrodes directly on the second semiconductor layers of the plurality of common electrode elements and in direct contact with the common electrode connection parts.

7. The display device of claim 1, further comprising an insulating layer around side surfaces of the plurality of light emitting elements and having portions directly on the common electrode layer, reflective layers around the side surfaces of the plurality of light emitting elements on the insulating layer, and a base layer on the common electrode layer and comprising an undoped semiconductor.

8. The display device of claim 7, further comprising a plurality of dummy elements each including the first semiconductor layer, the active layer, and the second semiconductor layer and located on the first substrate,
wherein the plurality of dummy elements have outer surfaces covered by the insulating layer.

9. The display device of claim 8, wherein the second semiconductor layer of one of the plurality of dummy elements is connected to the common electrode layer, the one of the plurality of dummy elements not being electrically connected to any of the plurality of pixel electrodes.

10. The display device of claim 8, wherein the plurality of light emitting elements comprises first light emitting elements comprising a first active layer to emit light of a first color and second light emitting elements comprising a second active layer different from the first active layer and to emit light of a second color, and
wherein the plurality of dummy elements comprises first dummy elements comprising the first active layer and second dummy elements comprising the second active layer.

11. The display device of claim 8, wherein each of the plurality of dummy elements is spaced from the first substrate.

12. A display device comprising:
a first substrate including a display area and a non-display area around the display area;
a plurality of pixel electrodes spaced from each other on the first substrate in the display area;
a plurality of common electrode connection parts on the first substrate in a common electrode area in the non-display area that is at one side of the display area;
a plurality of light emitting elements on corresponding ones of the plurality of pixel electrodes;
a plurality of common electrode elements on corresponding ones of the plurality of common electrode connection parts;
a common electrode layer on the plurality of light emitting elements and the plurality of common electrode elements in the display area and the non-display area; and
a plurality of connection electrodes between the plurality of light emitting elements and the plurality of pixel electrodes and between the plurality of common electrode elements and the plurality of common electrode connection parts,
wherein at least some of the plurality of connection electrodes are on side surfaces of the plurality of common electrode elements.

13. The display device of claim 12, wherein each of the plurality of light emitting elements and the plurality of common electrode elements comprises a first semiconductor layer comprising a p-type semiconductor, a second semiconductor layer on the first semiconductor layer and comprising an n-type semiconductor, and an active layer between the first semiconductor layer and the second semiconductor layer, and
wherein one of the plurality of connection electrodes on a corresponding one of the plurality of common electrode elements is in contact with the first semiconductor layer and the second semiconductor layer of the one of the plurality of common electrode elements.

14. The display device of claim 13, wherein the plurality of light emitting elements comprises first light emitting elements comprising a first active layer to emit light of a first color and second light emitting elements comprising a second active layer different from the first active layer and to emit light of a second color, and
wherein the plurality of common electrode elements comprises first common electrode elements comprising the first active layer and second common electrode elements comprising the second active layer.

15. The display device of claim 14, further comprising a plurality of dummy elements in an area other than the common electrode area in the non-display area, each of the plurality of dummy elements comprising the first semiconductor layer, the active layer, and the second semiconductor layer,
wherein the plurality of dummy elements comprises first dummy elements comprising the first active layer and second dummy elements comprising the second active layer.

16. The display device of claim 15, wherein the common electrode layer comprises an n-type semiconductor integrated with the second semiconductor layers of the plurality of light emitting elements, the plurality of common electrode elements, and the plurality of dummy elements.

17. A method for fabrication of a display device, the method comprising:
forming a support layer on a common electrode layer comprising an n-type semiconductor, forming a plurality of holes penetrating through the support layer, and forming a plurality of semiconductor elements in the holes, each of the plurality of semiconductor elements comprising a first semiconductor layer that is a p-type semiconductor, a second semiconductor layer that is an n-type semiconductor, and an active layer between the first semiconductor layer and the second semiconductor layer;
forming a plurality of light emitting elements by forming an insulating layer covering the plurality of semiconductor elements and the common electrode layer and removing portions of the insulating layer to expose upper surfaces of the first semiconductor layers of some of the plurality of semiconductor elements;
forming first connection electrodes on the exposed first semiconductor layers of the plurality of light emitting elements and forming reflective layers on the insulating layer to be around side surfaces of the plurality of light emitting elements and the plurality of semiconductor elements;
forming a plurality of common electrode elements by removing portions of the insulating layer and the reflective layers to expose outer surfaces of some other of the plurality of semiconductor elements;
forming second connection electrodes on the first connection electrodes and third connection electrodes on at least side surfaces of the plurality of common electrode elements; and
disposing the plurality of light emitting elements and the plurality of common electrode elements on a circuit substrate comprising a plurality of pixel electrodes and common electrode connection parts.

18. The method for fabrication of a display device of claim 17, wherein in the forming of the plurality of common electrode elements, the insulating layer and the reflective layers on some other of the plurality of semiconductor elements are not removed, such that a plurality of dummy elements are formed, and the third connection electrodes are on at least the side surfaces of the plurality of common electrode elements to be in direct contact with each of the first semiconductor layers and the second semiconductor layers.

19. The method for fabrication of a display device of claim 17, wherein the plurality of semiconductor elements comprises first semiconductor elements comprising a first active layer and second semiconductor elements comprising a second active layer, and
wherein the forming of the plurality of semiconductor elements comprises:
forming first holes penetrating through the support layer and forming the second semiconductor elements on the common electrode layer exposed by the first holes; and
forming second holes penetrating through the support layer and forming the first semiconductor elements on the common electrode layer exposed by the second holes.

20. The method for fabrication of a display device of claim 19, wherein the plurality of light emitting elements comprises first light emitting elements comprising the first active layer and second light emitting elements comprising the second active layer, and
wherein the plurality of common electrode elements comprises first common electrode elements comprising the first active layer and second common electrode elements comprising the second active layer.
